(19) United States
(12) Patent Application Publication
(10) Pub. No.: US 2017/0072436 A1
(43) Pub. Date: Mar. 16, 2017

(54) COATED FILM REMOVING APPARATUS

(71) Applicant: TOPPAN PRINTING CO., LTD., Taito-ku (JP)

(72) Inventors: Yuji KUBO, Taito-ku (JP); Rui Kanbayashi, Taito-ku (JP); Tomoaki Fukuhara, Taito-ku (JP); Hirotake Ito, Taito-ku (JP)

(73) Assignee: TOPPAN PRINTING CO., LTD., Taito-ku (JP)

(21) Appl. No.: 15/217,825

(22) Filed: Jul. 22, 2016

Related U.S. Application Data
(63) Continuation of application No. PCT/JP2015/000306, filed on Jan. 23, 2015.

(30) Foreign Application Priority Data
Jan. 24, 2014 (JP) 2014-010942
Mar. 26, 2014 (JP) 2014-064042
Apr. 17, 2014 (JP) 2014-085644
May 26, 2014 (JP) 2014-108130
May 27, 2014 (JP) 2014-109278

(51) Int. Cl. B08B 3/12; G03F 7/42; H01L 51/56; B08B 3/08

(52) U.S. Cl. CPC B08B 3/12; B08B 3/08; G03F 7/42; H01L 51/56

(57) ABSTRACT

An apparatus for removing a film coated on a substrate includes a film removing body including a liquid supply device which discharges removing liquid through a discharge opening to a removal portion of a film coated on a substrate, and a collection device which collects a discharged removing liquid through a collection opening, and an adjustment device that adjusts a distance between a surface of the substrate to a bottom surface of the film removing body at a position between the discharge opening and the collection opening.

### CROSS-REFERENCE TO RELATED APPLICATIONS

The present application is a continuation of International Application No. PCT/JP2015/000306, filed Jan. 23, 2015, which is based upon and claims the benefits of priority to Japanese Application No. 2014-010942, filed Jan. 24, 2014, Japanese Application No. 2014-064042, filed Mar. 26, 2014, Japanese Application No. 2014-085644, filed Apr. 17, 2014, Japanese Application No. 2014-108130, filed May 26, 2014, and Japanese Application No. 2014-109278, filed May 27, 2014. The entire contents of all of the above applications are incorporated herein by reference.

### BACKGROUND OF THE INVENTION

Field of the Invention

The present invention relates to a coated film removing apparatus which selectively removes a coated film formed on a substrate in a manufacturing process of a polymer organic EL display panel or the like.

Discussion of the Background

In a manufacturing process of a polymer organic EL display panel or the like, films (layers) may be formed by using a coating method to compose the polymer organic EL display panel or the like. When a film is formed, part of the film formed in a region requiring no film-formation, i.e., in a film-formation-unneeded region, may have to be removed. For example, PTLs 1 and 2 disclose methods for removing a film.
PTL 1: JP-A-H08-102434
PTL 2: JP-A-H11-143088

### SUMMARY OF THE INVENTION

According to one aspect of the present invention, an apparatus for removing a film coated on a substrate includes a film removing body including a liquid supply device which discharges removing liquid through a discharge opening to a removal portion of a film coated on a substrate, and a collection device which collects a discharged removing liquid through a collection opening, and an adjustment device that adjusts a distance between a surface of the substrate to a bottom surface of the film removing body at a position between the discharge opening and the collection opening.

According to another aspect of the present invention, an apparatus for removing a film coated on a substrate includes a film removing body including a liquid supply device which discharges removing liquid to a removal portion of a film coated on a substrate, and a collection device which collects a discharged removing liquid through a collection opening. The liquid supply device has at least one discharge opening for discharging the removing liquid, and the collection device has at least one collection opening for collecting the removing liquid.

According to still another aspect of the present invention, an apparatus for removing a film coated on a substrate includes a film removing body including a liquid supply device which discharges removing liquid through a discharge opening to a removal portion of a film coated on a substrate, and a collection device which collects a discharged removing liquid through a collection opening. The film removing body has a bottom surface between the discharge opening and the collection opening, and the film removing body has a bottom surface positioned at a distance from a surface of the substrate, and the distance measured at a first position of the bottom surface where the discharge opening is located is different from the distance measured at a second position of the bottom surface where the collection opening is located.

### BRIEF DESCRIPTION OF THE DRAWINGS

A more complete appreciation of the invention and many of the attendant advantages thereof will be readily obtained as the same becomes better understood by reference to the following detailed description when considered in connection with the accompanying drawings, wherein:

FIGS. 1(a)-1(d) are plan views showing a configuration of a coated film removing apparatus according to first to fourth embodiments, in which

FIG. 1(a) illustrates a state where a process gap measurement device is measuring distance between a coated film removal portion in the coated film formed on a substrate surface, and a discharge outlet and a collection inlet of a coated film removing unit (vertical unit), FIG. 1(b) illustrates a state where the coated film removing unit (vertical unit) is operating for a film-formation-unneeded region in the vertical direction, FIG. 1(c) illustrates a state where a coated film removing unit (horizontal unit) is operating for a film-formation-unneeded region in the horizontal direction, and FIG. 1(d) illustrates a state where the coated film has been removed for all the film-formation-unneeded region.

FIG. 2 is a perspective view showing an operation example of the coated film removing apparatus according to the first to fourth embodiments.

FIG. 3 is an example of a cross sectional view showing a removing unit 31 taken along a line A-A shown in FIG. 1 (d).

FIG. 4 is a cross sectional view showing an example of a coated film removing apparatus having an ultrasonic vibration application unit according to the first embodiment.

FIG. 5 is a plan view showing a first modification of the coated film removing apparatus according to the first embodiment.

FIG. 6 is a plan view showing a second modification of the coated film removing apparatus according to the first embodiment.

FIG. 7 is a perspective view showing an operation example of the second modification according to the first embodiment.

FIG. 8 is an example of a cross sectional view showing a removing unit 32 shown in FIG. 1 (d) taken along a line Ba-Bb.

FIG. 9 is an example of a cross sectional view showing a removing unit 33 shown in FIG. 1 (d) taken along a line Ba-Bb.

FIG. 10 is a perspective view showing an operation example of a coated film removing apparatus according to a fourth embodiment.

FIGS. 11(a) and 11(b) are examples of a cross sectional view showing a removing unit 34 shown in FIG. 1(d) taken along a line Ba-Bb, in which a droplet of removing liquid move towards a smaller part of a gap.

FIGS. 12(a)-12(d) are plan views showing a configuration of a coated film removing apparatus according to a fifth embodiment, in which FIG. 12(a) illustrates a state where a coated film removing apparatus is removing a coated film, FIG. 12(b) illustrates a state where the coated film is being removed after the process shown in FIG. 12 (a), FIG. 12(c) illustrates a state where the coated film is being removed after the process shown in FIG. 12 (b), and FIG. 12(d) illustrates a state where the coated film is being removed after the process shown in FIG. 12 (c).

FIG. 13 is diagrams of a front view, a plan view and a side view, showing a coated film removing apparatus according to the fifth embodiment.

FIG. 14 is a perspective view showing an operation example of the coated film removing apparatus according to the fifth embodiment.

FIGS. 15(a) and 15(b) are cross sectional views showing a configuration of the coated film removing apparatus according to the fifth embodiment, in which FIG. 15(a) illustrates a cross-sectional view taken along a line I-I shown in FIG. 12 (a), FIG. 15(b) illustrates a cross-sectional view taken along a line II-II shown in FIG. 12 (a).

FIGS. 16(a) and 16(b) are plan views showing a film-formation-unneeded region on a substrate according to the fifth embodiment, in which FIG. 16(a) illustrates a film-formation-unneeded region in the Y-axis direction on the substrate, and FIG. 16(b) illustrates a film-formation-unneeded region in the X-axis direction on the substrate.

FIGS. 17(a)-17(d) are plan views showing a state where a coated film removing apparatus is removing a coated film according to the fifth embodiment, in which FIG. 17(a) illustrates a state where a coated film removing apparatus is removing a coated film in a practical example, FIG. 17(b) illustrates a state where the coated film is being removed after the process shown in FIG. 17 (a), FIG. 17(c) illustrates a state where the coated film is being removed after the process shown in FIGS. 17 (b), and FIG. 17(d) illustrates a state where the coated film is being removed after the process shown in FIG. 17 (c).

FIG. 18 is an example of a cross sectional view of a removing unit 35 shown in FIG. 17 (a) taken along a line III-III.

FIG. 19 is a perspective view showing an operation example of the coated film removing apparatus according to the fifth embodiment.

FIGS. 20(a) and 20(b) are plan views showing a film-formation-unneeded region on a substrate of a practical example according to the fifth embodiment, in which FIG. 20(a) illustrates a film-formation-unneeded region in the Y axis direction, and FIG. 20(b) illustrates a film-formation-unneeded region in the X axis direction.

### DESCRIPTION OF THE EMBODIMENTS

The embodiments will now be described with reference to the accompanying drawings, wherein like reference numerals designate corresponding or identical elements throughout the various drawings.

Hereinafter, with reference to the drawings, each coated film removing apparatus according to first to fifth embodiments will be described. In the following detailed description, various specific details will be described to provide a complete understanding of the embodiments of the present invention. However, it would be apparent that one or more embodiments can be implemented without the specific details. Further, to simplify the drawings, known structures and apparatus are schematically illustrated. Moreover, in the drawings, an identical reference sign is given to elements having similar or analogous functions, and duplicated explanation is omitted.

### First Embodiment

With reference to the drawings, hereinafter, a coated film removing apparatus 101 according to a first embodiment of the present invention will be described.

(Overall Configuration of the Coated Film Removing Apparatus 101)

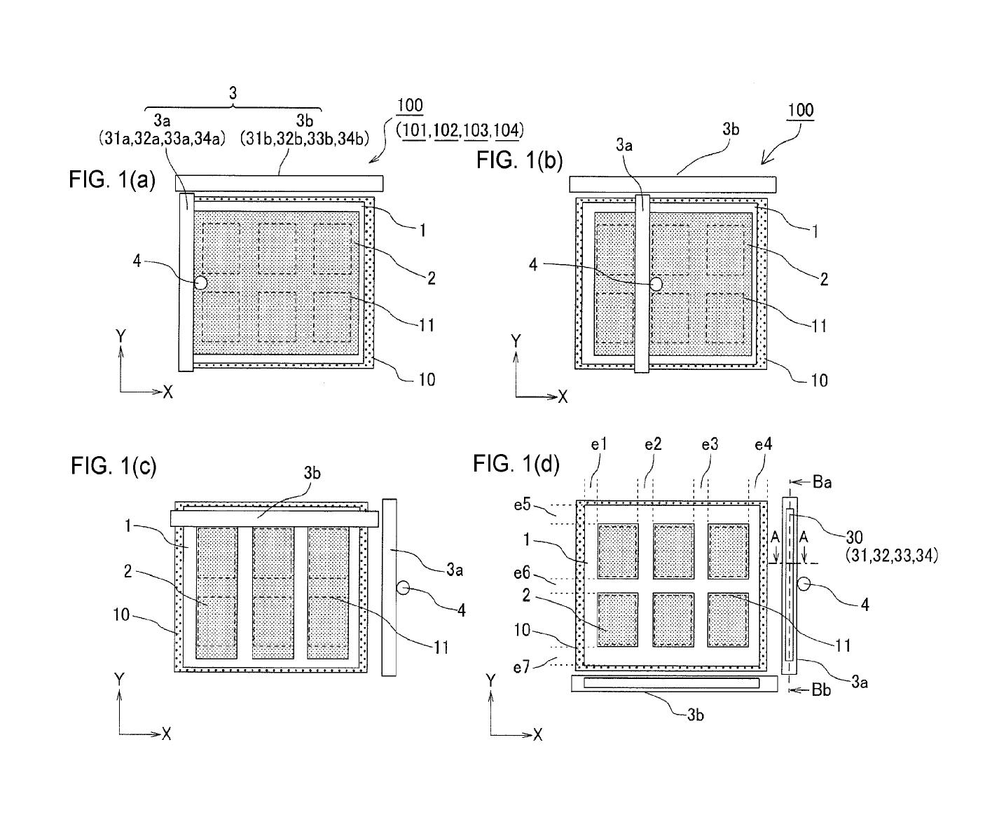

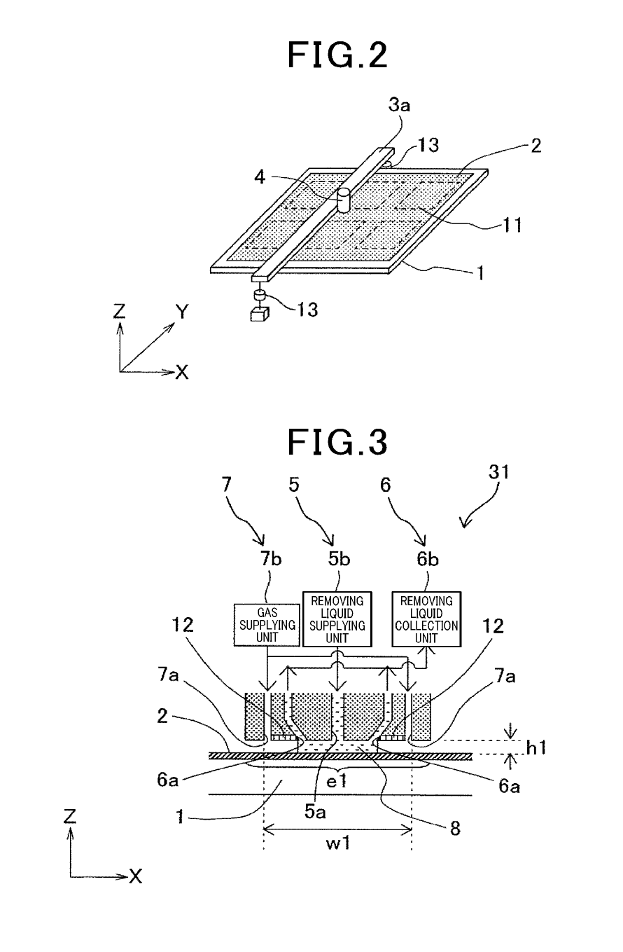

FIGS. 1(a)-1(d) are overall configuration diagrams showing the coated film removing apparatus 101 according to the first embodiment of the present invention. FIG. 2 is a perspective view showing an operation example of the coated film removing apparatus according to the first embodiment of the present invention. In FIGS. 1(a)-1(d), coated film removing apparatuses 101 to 104 according to the first to fourth embodiments, which will be described later, are shown as a coated film removing apparatus 100. Moving units 31a to 34a according to the first to fourth embodiments, which will be described later, are shown as a moving unit 3a, and moving units 31b to 34b according to the first to fourth embodiments, which will be described later, are shown as a moving unit 3b.

The coated film removing apparatus 101 removes a coated film removal portion that is a part of the coated film on a substrate. In other words, the coated film removing apparatus 101 removes a coated film of the coated film removal portion coated on the film-formation-unneeded region which requires no coating of film thereon.

In FIGS. 1(a)-1(d), reference sign 1 shows a substrate having a coated film to be removed, symbol 2 shows a coated film formed on the substrate 1, and symbol 11 shows a necessary film-formation region in the film coated on the substrate 1. Hence, a coated film portion other than the necessary-film formation region 11 is a region of the coated film removal portion, i.e., film-formation-unneeded regions e1 to e7 representing regions where the coated film should be selectively removed.

The coated film removing apparatus 101 is provided with a coated film removing body 3, a stage 10 that chucks and holds the substrate 1 having a coated film to be removed, and a process gap adjustment device 13 (see FIG. 2).

The coated film removing body 3 is provided with a coated film removing body (vertical unit) 31a (hereinafter may also be simply referred to as a moving unit), and a coated film removing body (horizontal unit) 31b (hereinafter may also be simply referred to as a moving unit). The coated film removing body (vertical unit) 31a moves in a left-right direction of the stage 10 shown in FIGS. 1(a)-1(d), removing a coated film in the vertical direction (Y-axis direction in FIGS. 1(a)-1(d)) with respect to the substrate 1, and the coated film removing body (horizontal unit) 31b moves in a front-back direction of the stage 10 shown in FIGS. 1(a)-1(d), removing a coated film in the horizontal direction (X-axis direction in FIGS. 1(a)-1(d)) with respect to the substrate 1.

The moving unit 31a is disposed along the Y-axis direction of the stage 10, bridging over the substrate 1 chucked and held on the stage 10. The moving unit 31a has a process gap measurement device 4 (hereinafter may also be simply referred to as a height measurement device) supported thereon. The height measurement device 4 measures a distance between a surface of the substrate 1 and a bottom surface of the moving unit 31a (i.e., gap) h1. A process gap adjustment device 13 (hereinafter may also be simply referred to as a height adjustment device) lifts up or down the moving unit 31a such that the distance h1 measured by the height measurement device 4 becomes a prescribed value set in advance. The moving unit 31a is moved in the X-axis direction and the height direction, i.e., Z-axis direction, for example, by a guide and a lifting mechanism (both are not shown) disposed at both ends of the Y-axis direction of the stage 10, along the X-axis direction. Thus, for example, as shown in FIGS. 2 and 3, the moving unit 31a moves in the X-axis direction, maintaining a prescribed distance h1 between the surface of the substrate 1 and the moving unit 31a.

As shown in FIGS. 1(a)-1(d), in the first embodiment, a necessary film-formation region 11 is arranged in a lattice pattern. Based on this arrangement, the moving unit 31b is disposed being shifted by 90 degrees with respect to the moving unit 31a in plan view. In other words, the moving unit 31b is disposed along the X-axis direction of the stage 10, bridging over the substrate 1 chucked and held on the stage 10. When operating the moving units 31a and 31b, a processing height position of the moving unit 31b is adjusted to that of the moving unit 31a. Specifically, the process gap adjustment device 13 lifts up or down the moving unit 31b, with respect to the distance h1 measured by the height measurement device 4 fixed to the moving unit 31a, such that the distance h1 between the surface of the substrate 1 and the moving unit 31b becomes a prescribed value. The moving unit 31b is moved in the Y-axis direction and the Z-axis direction, for example, by a guide and a lifting mechanism (both are not shown) disposed at both ends in the X-axis direction of the stage 10, along the Y-axis direction. Thus, the moving unit 31b is ensured to move in the Y-axis direction of the substrate 1. In other words, the moving units 31a and 31b only need to be capable of moving in two directions, for example, by setting an orthogonal coordinate with respect to a direction in which the necessary film-formation regions 11 are arrayed.

According to the first embodiment, the lifting mechanism is configured of the height adjustment device 13. In particular, the lifting mechanism may be configured of height adjustment devices 13 disposed at both end portions of the moving units 31a and 31b.

The height measurement device 4 may not be fixed to the moving unit 31a but may be fixed to the moving unit 31b. Moreover, for example, the height measurement device 4 may be configured to move in the X-axis direction by means of a guide (not shown) arranged at both ends of the Y-axis direction of the stage 10, along the X-axis direction, thereby independently scanning the substrate in the X-axis direction. Also, for example, the height measurement device 4 may be configured to move in the Y-axis direction by means of a guide (not shown) arranged at both ends of the X-axis direction of the stage 10, along the Y-axis direction, thereby scanning the substrate in the Y-axis direction. In short, the height measurement device 4 may be configured such that the distance h1 from the moving units 31a and 31b to the surface (surface of the coated film) of the substrate 1 can be measured, and the height adjustment device 13 can adjust, based on the measured value, the distance h1 with respect to the surface of the substrate 1 so as to be within the prescribed value.

Each of the moving units 31a and 31b is movable along the substrate 1 by using a drive unit (not shown). In each of the moving units 31a and 31b, a removing unit 31 is disposed, so as to face the film-formation-unneeded region which is a region excluding the necessary film-formation region 11 of the substrate 1. In other words, as shown in FIG. 1(d), the film-formation-unneeded region extending in the Y-axis direction of the substrate 1 is defined as e1, e2, e3 and e4 in the order from left to right, and the film-formation-unneeded region extending in the X-axis direction of the substrate 1 is defined as e5, e6 and e7 in the order from top to bottom. Then, the moving unit 31a is moved, by the drive unit, to a position where the removing unit 31 faces the film-formation-unneeded region e1, and removes the coated film. The moving unit 31a repeatedly performs positional movement and removal of the coated film, until the coated film in the film-formation-unneeded region e1 is removed. Similarly, the coated film is removed for the film-formation-unneeded regions e2 to e4.

On the other hand, the moving unit 31b is moved, by the drive unit, to a position where the removing unit 31 faces the film-formation-unneeded region e5, and removes the coated film. The moving unit 31b repeatedly performs positional movement and removal of the coated film, until the coated film in the film-formation-unneeded region e5 is removed. Similarly, the coated film is sequentially removed for the film-formation-unneeded regions e6 and e7. The removing units 31 of the moving units 31a and 31b have the same configuration. However, configuration is not limited to this one.

(Configuration of Removing Unit 31)

FIG. 3 is an example of a cross sectional view showing the removing unit 31 taken along a line A-A shown in FIG. 1 (d). As shown in FIG. 3, the removing unit 31 is provided with a removing liquid supplying means 5, a removing liquid collection means 6 and a gas supplying unit 7.

The removing liquid supplying means 5 is provided with a removing liquid supplying opening 5a and a removing liquid supplying unit 5b which supplies removing liquid 8 to the removing liquid supplying opening 5a. The removing liquid supplying opening 5a is provided in the removing unit 31 so as to face the film-formation-unneeded region (e.g., e1) on the substrate 1. When activating the removing liquid supplying unit 5b, the removing liquid 8 for removing the coated film 2 is supplied to the removing liquid supplying opening 5a by the removing liquid supplying unit 5b, and the removing liquid 8 is discharged onto the substrate 1 from an opening end of substrate 1 side of the removing liquid supplying opening 5a. The removing liquid supplying unit 5b is constituted of a syringe pump or the like which is capable of discharge with constant quantity, and discharges a constant quantity of the removing liquid 8 onto the substrate 1 through the removing liquid supplying opening 5a.

The removing liquid collection means 6 is provided with a removing liquid collection opening 6a disposed facing the film-formation-unneeded region (e.g., e1) on the substrate 1 and a removing liquid collection unit 6b. A plurality of removing liquid collection openings 6a are arranged, for example, to pinch the removing liquid supplying opening 5a therebetween. As shown in FIG. 3, the opening ends of the removing liquid collection openings 6a facing the substrate 1 are bent towards the removing liquid supplying opening 5a. It should be noted that a cross-sectional configuration of the removing unit 31, or, in particular, configurations of the removing liquid supplying opening 5a and the removing liquid collection opening 6a, and positional relationship therebetween are not limited to these configurations and positional relationship.

The removing liquid collection unit 6b includes, for example, a suction device such as an ejector tank. With the activation of the removing liquid collection unit 6b, the removing liquid 8 on the substrate 1 is collected in the removing liquid collection unit 6b via the removing liquid collection opening 6a.

A water repellent outer unit 12 is formed to pinch the removing liquid collection openings 6a. As a result, the removing liquid 8 is prevented from wet-spreading outside by being discharged from the removing liquid supplying opening 5a located inside the water repellent outer unit 12.

As shown in FIG. 3, the gas supplying unit 7 is provided with a gas supplying opening 7a disposed facing the film-formation-unneeded region (e.g., e1) on the substrate 1, and a gas supplying unit 7b. The gas supplying opening 7a is formed to pinch the removing liquid collection openings 6a. When the gas supplying unit 7b is activated, a gas (e.g., air) blows against the substrate 1.

As shown in FIG. 3, the gas supplying opening 7a has a width W1 along the longitudinal direction of the moving unit 31a. The width w1 is set to be slightly shorter than the width of the film-formation-unneeded region e1, along the longitudinal direction of the moving unit 31a.

When the gas supplying unit 7b is activated, the air blowing from the gas supplying opening 7a serves as an air curtain. Hence, the removing liquid 8 is prevented from dispersing or flowing outside the film-formation-unneeded region e1, when discharged from the removing liquid supplying opening 5a provided inward of the gas supplying opening 7a.

The removing unit 31 having the above-mentioned configuration activates the removing liquid supplying means 5, the removing liquid collection means 6 and the gas supplying unit 7, with the moving unit 31a being moved to face the film-formation-unneeded regions e1 to e4, whereby the removing liquid 8 is ensured to be prevented from flowing outside the film-formation-unneeded regions e1 to e4, while being discharged onto the film-formation-unneeded regions e1 to e4 and collected.

In the case of the moving unit 31b, for example, as shown in FIG. 1 (d), the removing liquid supplying means 5, the removing liquid collection means 6 and the gas supplying unit 7 can be activated, with the moving unit 31b being moved such that the film-formation-unneeded regions e5 to e7 face the removing unit 31.

The removing liquid supplying unit 5b, the removing liquid collection unit 6b and the gas supplying unit 7b may be provided separately from the moving unit 31a. In this case, the removing liquid supplying unit 5b may be connected to the removing liquid supplying opening 5a via a deformable removing liquid supplying tube. Similarly, the removing liquid collection unit 6b may be connected to the removing liquid collection opening 6a via a deformable removing liquid collecting tube. Also, the gas supplying unit 7b may be connected to the gas supplying opening 7a via a deformable air supplying tube. Further, not all of the removing liquid supplying unit 5b, the removing liquid collection unit 6b and the gas supplying unit 7b necessarily have to be disposed in the moving units 31a and the 31b. However, at least one of the removing liquid supplying unit 5b, the removing liquid collection unit 6b and the gas supplying unit 7b may be disposed in the moving units 31a and the 31b.

Since the removing unit 31 disposed in the moving units 31a and 31b only has to be provided facing the film-formation-unneeded regions e1 to e7 which are regions excluding the necessary film-formation region 11 to remove the coated film, as shown in FIG. 5, a plurality of removing units 31 may be arranged at positions on the moving unit 31a so as to face the respective film-formation-unneeded regions e5 to e7. Similarly, a plurality of removing units 31 may be arranged at positions on the moving unit 31b so as to face the respective film-formation-unneeded regions e1 to e4. The removing units 31 in this case have the same configuration.

An arrangement of the removing liquid supplying opening 5a, the removing liquid collection opening 6a and the water repellent outer unit 12 in the removing unit 31 is not limited to the above-described embodiments. For example, a plurality of removing liquid supplying openings 5a may be arranged. The removing liquid collection openings 6a are arranged to pinch the removing liquid supplying opening 5a. However, the removing liquid collection openings 6a may be arranged to squarely or circularly surround the removing liquid supplying opening 5a. The removing liquid collection openings 6a may be arranged randomly at an outer peripheral side of the removing liquid supplying opening 5a. The water repellent outer unit 12 is arranged to pinch the removing liquid supplying opening 5a and the removing liquid collection openings 6a. However, the water repellent outer unit 12 may be arranged to squarely or circularly surround the removing liquid collection openings 6a. Moreover, the water repellent outer unit 12 may be arranged randomly at a position facing the vicinity of the boundary portion in the film-formation-unneeded region. In short, any configurations may be employed as long as the removing liquid supplying opening 5a and the removing liquid collection openings 6a are within an area surrounded by the water repellent outer unit 12, and water repellent properties of the water repellent outer unit 12 prevent the removing liquid 8 discharged from the removing liquid supplying opening 5a from moving towards outside the film-formation-unneeded region.

The arrangement of the removing liquid supplying opening 5a, the removing liquid collection opening 6a, the water repellent outer unit 12, and the gas supplying opening 7a in the removing unit 31 is not limited to the above-described embodiments. For example, the gas supplying opening 7a, which has been arranged to pinch the removing liquid supplying opening 5a, the removing liquid collection opening 6a and the water repellent outer unit 12, may be arranged to surround the removing liquid supplying opening 5a, the removing liquid collection opening 6a and the water repellent outer unit 12 in a square shape or a circular shape. Also, a plurality of gas supplying openings 7a may be arranged. The gas supplying openings 7a may be arranged randomly at a position facing the vicinity of the boundary portion in the film-formation-unneeded region. In short, any configurations may be employed as long as the removing liquid supplying opening 5a, the removing liquid collection openings 6a and the water repellent outer unit 12 are within an area surrounded by the air curtain of the gas supplying unit 7, and the removing liquid 8 discharged from the removing liquid supplying opening 5a is prevented from dispersing or flowing towards outside the film-formation-unneeded region.

(Operation and Others)

Hereinafter, an operation of the above-described embodiments will be described. As shown in FIGS. 1(a)-1(d), the height measurement device 4 measures the distance h1 between the surface of the substrate 1 and the moving unit 31a. Then, the moving unit 31a is arranged such that the height adjustment device 13 sets the distance h1 with respect to the surface of the substrate 1 to be within the prescribed value. Thereafter, the moving unit 31a is arranged, for example, facing the coated film 2 formed on the substrate 1, so as to be close to each other. Subsequently, the removing liquid 8 is discharged from the removing liquid supplying unit 5b via the removing liquid supplying opening 5a to a gap between the moving unit 31a and the substrate 1 where the coated film 2 is formed, so as to maintain the quantity of the removing liquid 8 to be constant. Then, this condition is maintained for a predetermined period.

The distance h1 set to the above-described prescribed value may preferably be set such that the removing liquid 8 between the moving unit 31a and the substrate 1 where the coated film 2 is formed is maintained within a constant range, according to properties of the removing liquid 8, such as a discharge quantity and viscosity.

The predetermined period should be a sufficient time for the removing liquid 8 to dissolve or peel off the coated film 2.

The removing liquid 8 is held on the film-formation-unneeded region for a predetermined period, whereby the coated film 2 is dissolved or peeled off. When the predetermined period has elapsed at which the coated film 2 is estimated to have been dissolved or peeled off, the removing liquid collection means 6 collects and drains the removing liquid 8 which is mixed with the coated film 2 between the moving unit 31a and the substrate 1. In other words, the removing liquid collection unit 6b is activated so as to collect the removing liquid 8 on the substrate 1 through the removing liquid collection opening 6a.

These processes, i.e., supplying and collecting the removing liquid 8 are repeatedly performed, whereby the coated film 2 present in the film-formation-unneeded region on the substrate 1 is removed. Hence, a complete clean surface of the substrate can be obtained.

Moreover, by activating the gas supplying unit 7, during a period from when the removing liquid supplying means 5 started to discharge the removing liquid 8 until the removing liquid 8 on the substrate 1 is collected, air is discharged onto the substrate 1 via the gas supplying openings 7a. As shown in FIG. 3, the gas supplying openings 7a are arranged around the removing liquid supplying opening 5a and the removing liquid collection opening 6a. Hence, with the air discharged from the gas supplying openings 7a, the removing liquid 8 discharged on the substrate 1 can be prevented from being dispersed or flowing outside the film-formation-unneeded region.

Then, as shown in FIG. 1(a), these operations are performed at individual positions, with the moving unit 31a being moved in the X-axis direction.

When moving unit 31a completes removal of the coated film of the film-formation-unneeded region extending in the Y-axis direction of the substrate 1, the coated film is removed, with a similar procedure, for the film-formation-unneeded region extending in the X-axis direction of the substrate 1 in the respective positions, as shown in FIG. 1(b), with the moving unit 31b being moved in the Y-axis direction.

Thus, with the moving units 31a and 31b being activated the coated film is removed, as shown in FIG. 1(d), only for the film-formation-unneeded region of the substrate 1.

It should be noted that the gas supplied by the gas supplying unit 7 may be an inactive gas, such as nitrogen gas, considering influences on the properties of the organic material used for the coated film 2.

As shown in FIG. 3, since the water repellent outer units 12 in which water repellent treatment is applied are arranged around the removing liquid supplying opening 5a and the removing liquid collection opening 6a, the water repellent properties of the water repellent outer unit 12 can contribute to preventing the removing liquid 8 discharged onto the substrate 1 from wet-spreading outside the film-formation-unneeded region. In other words, in addition to the effect of suppressing wet spread of the removing liquid 8 caused by the gas discharged from the gas supplying openings 7a, the coated film 2 of the necessary film-formation region 11 can be prevented from being undesirably removed. Therefore, only the coated film 2 existing in the film-formation-unneeded region can reliably be removed.

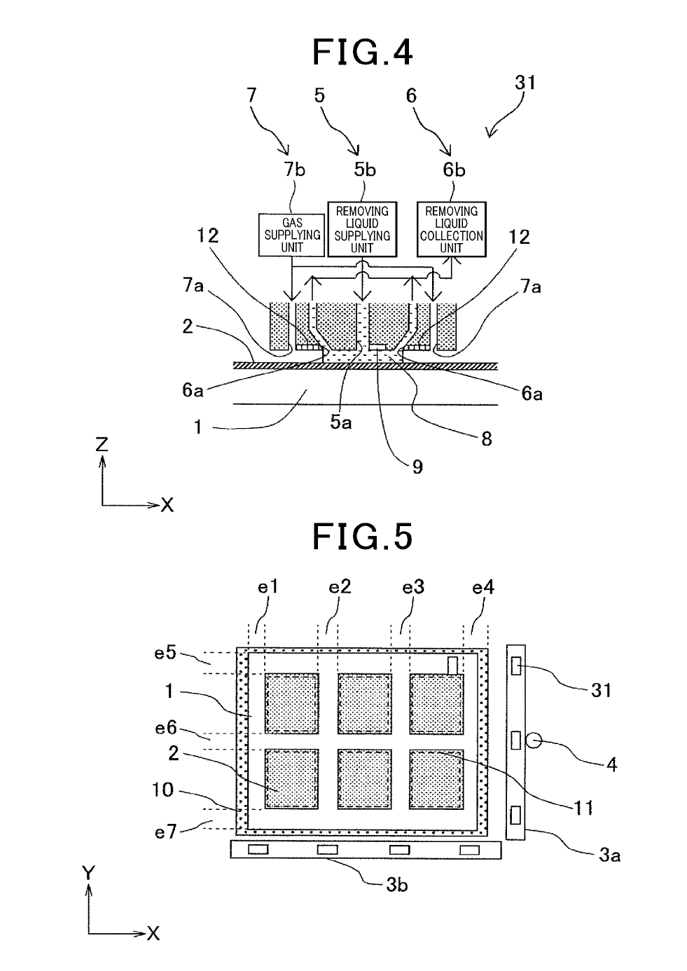

Further, the removing liquid 8 may be applied with ultrasonic vibration to improve the performance of removing the coated film 2. Specifically, as shown in FIG. 4, for example, an ultrasonic vibration application unit 9 can be provided at an opening end of the removing liquid supplying opening 5a and activated to vibrate the removing liquid 8.

The temperature of the discharged removing liquid 8 may be set to room temperature. However, considering the adverse effect of volatilization of the liquid, the temperature is set within a range from 30° C. to 40° C., whereby the coated film 2 can be effectively dissolved. As a result, processing time can be shortened and the coated film 2 can be more reliably removed.

As shown in FIGS. 1(a)-1(d), description of the first embodiment deals with the case where the coated film is removed from the entire surface of the substrate 1 by activating either of the moving units 31a and 31b at a time, which are arranged forming an angle of 90 degrees therebetween. However, method for removing a coating film is not limited to this case. For example, as shown in FIG. 5, a plurality of removing units 31 may be arranged in the moving units 31a and 31b having the height measurement device 4. For example, a plurality of is removing units 31 may be arranged at positions in the moving unit 31a so as to be opposed to respective film-formation-unneeded regions e5 to e7. Similarly, a plurality of removing units 31 may be arranged at positions in the moving unit 31b so as to be opposed to respective film-formation-unneeded regions e1 to e4. In this case, the removing units 31 may be movably arranged in the moving units 31a and 31b. Thus, if the removing process is applied to a plurality of substrates having different widths and intervals of the film-formation-unneeded regions, the removing process can be appropriately performed. For example, the removing process can be performed while the removing units 31 are shifted in position, or the removing process can be started after the positions of the removing units 31 are adjusted in conformity with the intervals of the film-formation-unneeded regions.

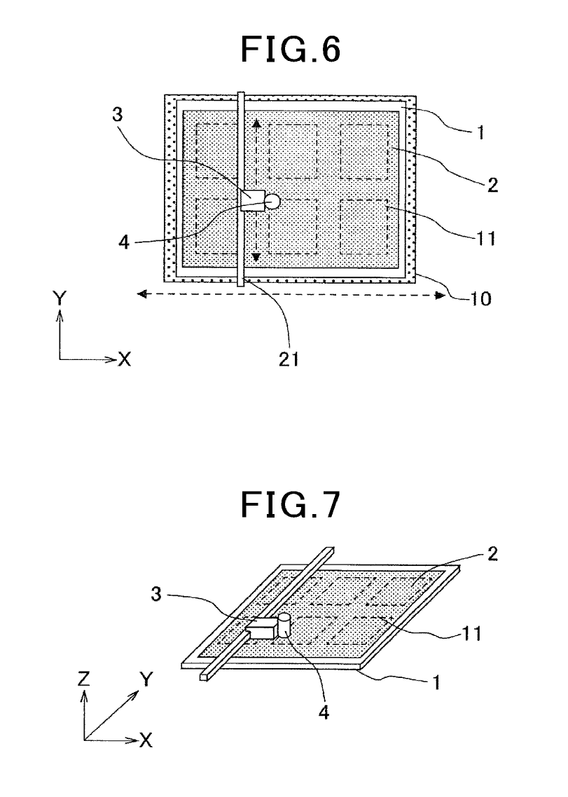

Further, for example, as shown in FIGS. 6 and 7, the coated film removing body 3 provided with the height measurement device 4 may be arranged movably in the Y-axis direction or the X-axis direction. As shown in FIG. 6, a guide rail 21 can be disposed along the Y-axis direction of the substrate 1 to stride over the substrate 1, and the coated film removing body 3 can be arranged movably to the guide rail 21. Moreover, guides (not shown) can be provided at lateral sides of the substrate 1 in the Y-axis direction so as to extend in the X-axis direction. By using the guides, a guide rail 21 can be arranged movably in the X-axis direction.

Then, the guide rail 21 is moved in the X-axis direction and the coated film removing body 3 is moved in the Y-axis direction on the guide rail 21, whereby the coated film removing body 3 can be moved in the X- and Y-axis directions, with respect to the substrate 1. As a result, the removing liquid can be supplied to and collected from the entire surface of the substrate 1 by the coated film removing body 3.

Depending on the balance of the time taken for removing the coated film and the control tact, either the configuration shown in FIGS. 1(a)-1(d) or the configuration shown in FIG. 6 can be selected.

As shown in FIG. 6, when using a configuration in which the coated film removing body 3 is provided in the guide rail 21, one removing unit 31 may be provided in the coated film removing body 3. When one removing unit 31 removes the coated film 2 in a plurality of film-formation-unneeded regions, there is a concern that the width w1 of the removing unit 31 cannot be appropriate with respect to the film-formation-unneeded regions, such as that the width w1 of the removing unit 31 is significantly narrower than that of the film-formation-unneeded region. In this case, for example, in FIG. 6, the coated film removing body 3 can be moved not only in the Y-axis direction but also in the X-axis direction, and the coated film removing body 3 can be moved in the Y-axis direction with fine adjustment in the X-axis direction, thereby removing the coated film.

In the above-described embodiments, an upper unit which is not shown may control a supply timing of the removing liquid 8 by the removing liquid supplying means 5, a collection timing of the removing liquid 8 by the removing liquid collection means 6 and a supply timing of the gas by the gas supplying unit 7. Also, the upper unit can control the drive unit driving the moving units 31a and 31b, and the coated film removing body 3, and control activation timings of the removing liquid supplying means 5, the removing liquid collection means 6 and the gas supplying unit 7, based on the positions of the moving units 31a and 31b, and the coated film removing body 3, thereby accurately removing the coated film 2 in the film-formation unneeded region.

As described above, the coated film removing apparatus 101 according to the first embodiment is configured to remove a coated film removal portion which is a part of the coated film 2 on the substrate 1. In other words, the coated film removing apparatus 101 removes the coated film 2 in the coated film removal portion coated on each of the film-formation unneeded regions e1 to e7 where coated film 2 is not needed.

As described above, portions excluding the necessary film-formation region 11 are defined as regions of the coated film removal portions in the coated film 2 which is coated on the substrate 1, i.e., the film-formation unneeded regions e1 to e7, where the coated film 2 should be selectively removed.

### Example 1

Hereinafter, the present invention will be described in more detail by way of examples.

### Example 1-1

As an example of a coated film removing apparatus 101 according to the first embodiment, in the following description sets forth the case where, in a film formation process of a hole transport layer of an organic EL display, an organic material is coated on the substrate 1 with a slit die to form the hole transport layer, and an unnecessary coated film 2 is removed in an outer periphery of the light emission region which is in a necessary film-formation range.

As a material of the hole transport layer to be coated, poly (3,4) ethylene dioxy thiophene/polystyrene sulfonic acid (PEDOT/PSS) was used, and as the removing liquid 8, pure water was used.

For the substrate 1, non-alkali glass OA-10 (manufactured by Nippon Electric Glass Co., Ltd), 120 mm×120 mm×0.7 mm was used, and the necessary film-formation range was set to 50 mm×50 mm. Then, an unnecessary coated film 2 formed outside the four outer peripheral sides was selectively removed.

First, the above-described hole transport layer material was coated, in a range of 100 mm×100 mm, on a cleaned substrate 1 using a slit die, followed by drying at 180° C. under a reduced pressure for an hour, thereby obtaining the coated film 2 with a thickness of 100 nm.

A range of 50 mm×50 mm around the center of a coated range of the hole transport layer material was assumed as a necessary film-formation region 11, and the coated film 2 was selectively removed from outside the four outer peripheral sides thereof using the coated film removing body 3 having the removing liquid supplying means 5 and the removing liquid collection means 6 shown in FIG. 3. The height of the coated film removing body 3 was adjusted based on a measurement value of a dial gauge attached to the coated film removing body 3 to set the distance h1 of 1 mm between the substrate 1 and the lower end of the coated film removing body 3. A syringe pump was used as the removing liquid supplying unit 5b of the removing liquid supplying means 5, enabling constant discharge, thereby determining the quantity of the removing liquid 8 that is held in the gap of the distance h1 between the substrate 1 and the coated film removing body 3.

According to the example 1-1, the distance h1 between the substrate 1 and a discharge opening of the coated film removing body 3 was set to 1 mm. To set the distance h1, it is necessary to select a combination of a discharge quantity of the removing liquid 8 and a desired processing width. When the distance h1 between the substrate 1 and the discharge opening of the coated film removing body 3 is widely set, a large discharge quantity is required in order to hold the removing liquid 8 in a gap of the distance h1 between the substrate 1 and the coated film removing body 3. Accordingly, the width of the removing liquid 8 held in the gap of the distance h1 between the substrate 1 and the coated film removing body 3 becomes larger.

On the other hand, when the distance h1 between the substrate 1 and the lower end of the coated film removing body 3 is narrowly set, the discharge quantity can be reduced. Hence, the width of the removing liquid 8 held in the gap of the distance h1 between the substrate 1 and the coated film removing body 3 can be made smaller. In other words, by adjusting the distance h1 between the substrate 1 and the coated film removing body 3, the width of the removing liquid 8, i.e., removal width of the coated film 2 can be adjusted to a desired range.

In the example 1-1, a dial gauge was used as the height measurement device 4. The device 4 is not limited to the dial gauge. However, a non-contact measurement device such as a laser displacement meter may preferably be used in view of minimizing scratches or foreign materials.

The removing liquid collection means 6 takes out exhaust, and is held between the substrate 1 and the coated film removing body 3 for a desired period to collect the removing liquid 8 in which the hole transport layer material has been dissolved. It was confirmed that almost all the coated film 2 was removed when the holding time was 30 seconds or more. Moreover, repeating the same operation once more, the remaining material which has not been collected can reliably be collected so that more favorable cleanness can be expected.

The coated film removing body 3 repeatedly scanned the substrate, changing a scanning direction by 90 degrees, and the unnecessary coated film was successively removed in the film-formation-unneeded region outside the four outer sides of the necessary film-formation range, achieving a state where there was no residual coated film in the outer periphery of the necessary film-formation range of 50 mm×50 mm. Also, in the coated film removing body 3, it was confirmed that water repellent properties of the water repellent outer unit 12 disposed outside the removing liquid supplying opening 5a and the removing liquid collection openings 6a prevented the removing liquid 8 from wet-spreading to the necessary film-formation range. It should be noted that a Teflon (registered trade mark) nickel plating was applied to the water repellent outer unit 12 on a surface facing the coated film 2, thereby obtaining water repellent properties having a water contact angle of 90 degrees.

Further, in the coated film removing body 3, the gas was supplied through the gas supplying opening 7a which was disposed outside the removing liquid supplying opening 5a and the removing liquid collection openings 6a, whereby a desired condition was confirmed where no removing liquid 8 was splashed into the necessary film-formation range.

### Example 1-2

In each of the conditions in the example 1-1, the temperature condition of the removing liquid 8 was 24° C. However, in the example 1-2, the temperature condition of the removing liquid 8 was changed to 30° C. from 24° C., and similar removing process was applied to the coated film 2. For conditions other than the temperature condition of the removing liquid 8, the same conditions as the example 1-1 were applied.

As a result, comparing with the case where the coated film 2 was removed in about 30 seconds when the temperature of the removing liquid 8 was 24° C., the period required for removing the coated film 2 was shortened to approximately 20 seconds, when the temperature of the removing liquid 8 was 30° C. Hence, the removal performance was significantly improved. When the temperature of the removing liquid 8 was increased more, the removal performance was further improved. However, when the temperature is set higher than 40° C., a gain in the removal performance is limited so that effect thereof is not significant. On the other hand, an adverse effect of steam is a concern. Therefore, when the temperature condition is determined, the apparatus and materials are needed to be taken care accordingly.

### Example 1-3

According to the example 1-3, the coated film 2 was removed by the coated film removing body 3 under the conditions of the example 1-2, i.e., with a temperature condition of the removing liquid 8 being 30° C., by applying ultrasonic vibration to the removing liquid 8 using an ultrasonic oscillator as the ultrasonic vibration application unit 9. The output power of the ultrasonic vibration was set to around 50 to 300 watts and the oscillation frequency was set to around 30 to 100 KHz.

As a result, comparing with the case where the coated film 2 was removed in about 20 seconds without applying ultrasonic vibration, the time taken for removing the coated film 2 was shortened to is approximately 15 seconds by applying ultrasonic vibration. Hence, the removing performance was confirmed to be significantly improved.

Thus, the coated film 2 can reliably be removed from an outer peripheral portion of an organic light emission pixel. This enables production of a polymer organic EL panel in which a simple coating method of uniformly forming a film is applied to a film-formation of a common layer, such as a hole transport layer and a hole injection layer, without the necessity of conducting coating on a pixel basis.

### Example 1-4

As a different example of a coated film removing apparatus 101 according to the first embodiment, in the following description sets forth the case where, in a film formation process of a photosensitive resin layer of a color filter used for liquid crystal display, an organic material forming the photosensitive resin layer is coated on the substrate 1 with a slit die, and unnecessary coated film 2 is removed in the outer periphery of a pixel region which is a necessary film-formation range.

As a material for a photosensitive resin to be coated, OFPR-800 manufactured by TOKYO OHKA KOGYO CO, LTD was used, and as the removing liquid 8, a sodium carbonate aqueous solution of 1.0 wt % at 30° C. was used.

For the substrate 1, non-alkali glass OA-10 (manufactured by Nippon Electric Glass Co., Ltd) of 120 mm×120 mm×0.7 mm was used, and the necessary film-formation range was set to 50 mm×50 mm. Then, the unnecessary coated film 2 formed outside the four outer peripheral sides was selectively removed.

First, the above-described photosensitive resin material was coated on a cleaned substrate 1 with a slit die in a range of 100 mm×100 mm, followed by drying under a reduced pressure of 1 Torr, thereby obtaining the coated film 2 with a thickness of 1.5 μm.

A range of 50 mm×50 mm around the center of a coated range of the photosensitive resin material was assumed as a necessary film-formation region 11, and the coated film 2 was selectively removed from outside the four outer peripheral sides thereof using the coated film removing body 3 having the removing liquid supplying means 5 and the removing liquid collection means 6 shown in FIG. 3. The height of the coated film removing body 3 was adjusted based on a measurement value of a dial gauge attached to the coated film removing body 3 to set the distance h1 of 1 mm between the substrate 1 and the lower end of the coated film removing body 3. A syringe pump was used as the removing liquid supplying unit 5b of the removing liquid supplying means 5, enabling constant discharge, thereby determining the quantity of the removing liquid 8 that is held in the gap of the distance h1 between the substrate 1 and the coated film removing body 3.

The removing liquid collection means 6 takes out exhaust, and is held between the substrate 1 and the coated film removing body 3 for a desired period to collect the removing liquid 8 in which the photo-sensitive resin material has been dissolved. It was confirmed that almost all the coated film 2 was removed when the holding time was 30 seconds or more. Moreover, repeating the same operation once more, the remaining material which has not been collected can reliably be collected so that more favorable cleanness can be expected.

The coated film removing body 3 repeatedly scanned the substrate, changing a scanning direction by 90 degrees, and the unnecessary coated film was successively removed in the is film-formation-unneeded region outside the four outer sides of the necessary film-formation range, achieving a state where there was no residual coated film in the outer periphery of the necessary film-formation range of 50 mm×50 mm. Also, in the coated film removing body 3, it was confirmed that water repellent properties of the water repellent outer unit 12 disposed outside the removing liquid supplying opening 5a and the removing liquid collection openings 6a prevented the removing liquid 8 from wet-spreading to the necessary film-formation range. It should be noted that a Teflon (registered trade mark) nickel plating was applied to the water repellent outer unit 12 on a surface facing the coated film 2, thereby obtaining water repellent properties having a water contact angle of 90 degrees.

Further, in the coated film removing body 3, the gas was supplied through the gas supplying opening 7a which was disposed outside the removing liquid supplying opening 5a and the removing liquid collection openings 6a, whereby a desired condition was confirmed where no removing liquid 8 was splashed into the necessary film-formation range.

Examples 1-1 to 1-4 of the present invention have been described so far. However, the present invention is not limited to these examples. In the above examples, organic EL displays and color filters used for liquid crystal display have been described. However, the present invention is not limited to these examples, but may be applied to a film formation substrate for other purposes. Also, the coated film 2 is not limited to materials used for organic EL such as a hole transport layer, or photosensitive resin materials used for color filters of liquid crystal displays, but may be applied to materials for other purposes. The removing liquid 8 can also be appropriately selected depending on the material of the coated film 2, for example, organic solvents and etchants or the like can be the candidates of selection.

### Second Embodiment

With reference to the drawings, hereinafter, a coated film removing apparatus 102 according to a second embodiment of the present invention will be described.

(Overall Configuration of Coated Film Removing Apparatus 102)

FIGS. 1(a)-1(d) are overall configurations showing the coated film removing apparatus 102 according to the second embodiment of the present invention.

FIG. 2 is a perspective view showing an operation example of the coated film removing apparatus 102 according to the second embodiment of the present invention. In FIG. 1(d), descriptions of the removing liquid supplying opening 5a and the removing liquid collection openings 6a according to the second embodiment are omitted.

As shown in FIGS. 1(a)-1(d), the configuration of the coated film removing apparatus 102 is approximately the same as the configuration of the coated film removing apparatus 101 according to the first embodiment. That is, the coated film removing apparatus 102 is provided with a coated film removing body 3, a stage 10 that chucks and holds the substrate 1 having a coated film 2 to be removed, and a height adjustment device 13. Similar to the first embodiment, the coated film removing body 3 according to the second embodiment is provided with a moving unit 32a and a moving unit 32b.

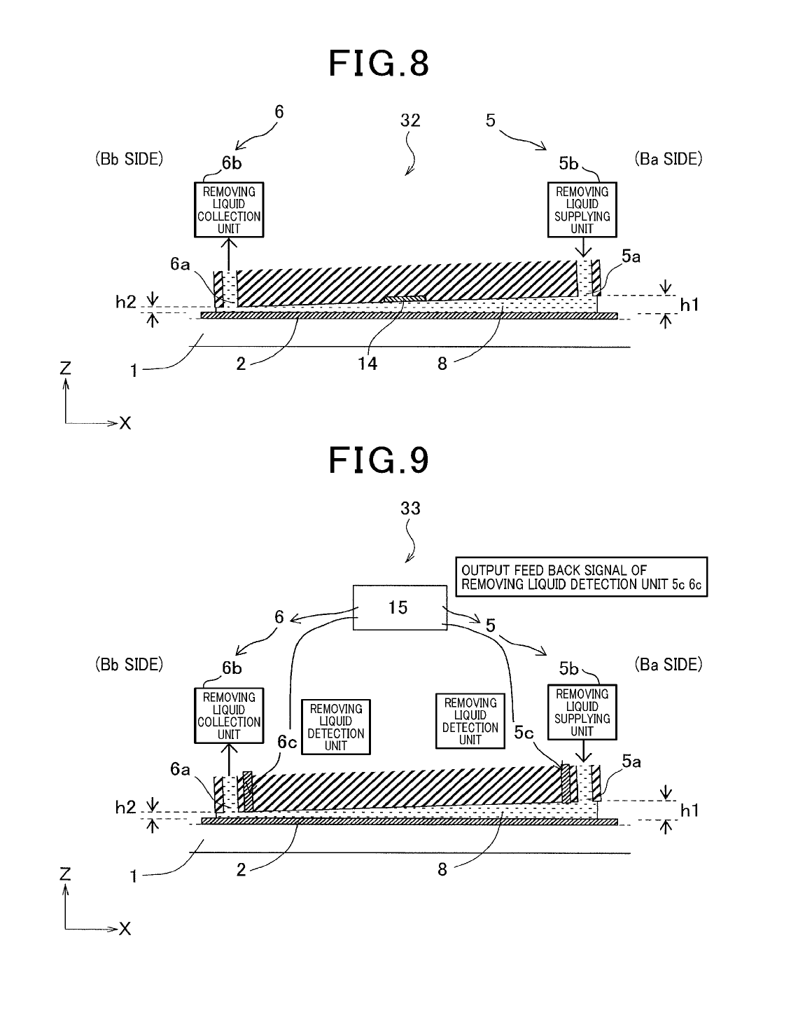

Similar to the first embodiment, the moving units 32a and 32b according to the second embodiment each include a removing unit 32. However, the removing units 32 according to the second embodiment is different from the removing unit 31 according to the first embodiment in the cross-sectional structure taken along the Ba-Bb line shown in FIG. 1 (d) (See FIG. 8).

Therefore, in the second embodiment, a structure of the removing unit 32 will be mainly described, omitting explanation on portions substantially the same as those of the first embodiment. Also, explanations of the operations and processes substantially the same as those described in the first embodiment will be omitted.

(Configuration of coated film removing body 3) The coated film removing body 3 according to the second embodiment is provided with a moving unit 32a and a moving unit 32b. As shown in FIGS. 1(a)-1(d), the moving unit 32a moves along the X-axis direction of the stage 10, removing the coated film in the Y-axis direction with respect to the substrate 1. The moving unit 32b moves along the Y-axis direction of the stage 10, removing the coated film in the X-axis direction with respect to the substrate 1.

The moving units 32a and 32b are ensured to be movable along the substrate 1 by a drive unit (not shown). In each of the moving units 32a and 32b, a removing unit 32 is disposed in an film-formation-unneeded region which is a region excluding the necessary film-formation region 11 on the substrate 1.

Similar to the above described moving unit 31a, the moving unit 32a moves in the X-axis direction and the Z-axis direction, for example, by a guide and a lifting mechanism (both are not shown) disposed on lateral sides of the stage 10 in the Y-axis direction, along the X-axis direction. Thus, for example, as shown in FIG. 8, the moving unit 32a is ensured to move in the X-axis direction of the substrate 1 in a state where the surface of the substrate 1 and the moving unit 32a are maintained being inclined to create predetermined distances h1 and h2 therebetween. In other words, the moving unit 32a is ensured to move in the X-axis direction of the substrate 1 in a state where the distance (first distance) h1 between the surface of the substrate 1 and the removing liquid supplying opening 5a side bottom surface of the coated film removing body 3 differs from the distance (second distance) h2 between the surface of the substrate 1 and the removing liquid collection opening 6a side bottom surface.

According to the second embodiment, the height measurement device 4 may only have to be configured to measure a distance h from the moving units 32a and 32b to the surface of the substrate 1 (coated film surface), and the height adjustment device 13 may be configured to adjust the height based on the measurement result such that the distances h1 and h2 with respect to the surface of the substrate 1 have prescribed values. Height adjustment devices 13 are disposed at both ends of the moving unit 32a, allowing the moving unit 32a to lift up/down and incline so as to set, with respect to the distance h measured by the height measurement device 4, the distances h1 and h2 from both ends of the moving unit 32a to the surface of the substrate 1 to predetermined values.

Moreover, the height adjustment devices 13 support the moving unit 32b, and allow the moving unit 32b to lift up/down and incline to set the distances h1 and h2 from the surface of the substrate 1 to the moving unit 32b have predetermined values, based on the distance h measured by the height measurement device 4 which is fixed to the moving unit 32a, when removing the coated film 2 of the coated film removal portions coated on the film-formation-unneeded regions e1 to e7 where no coated film 2 is required on the substrate 1.

In the second embodiment, as an example, the case where the above-described lifting mechanism constitutes the height adjustment device 13 will be described. The lifting mechanism may be constituted of the height adjustment devices 13 disposed at both ends of the moving units 32a and 32b.

(Configuration of Removing Unit 32)

FIG. 8 is an example of a cross sectional view showing the removing unit 32 shown in FIG. 1 (d) taken along a line Ba-Bb. As shown in FIG. 8, the removing unit 32 is provided with a removing liquid supplying means 5 and a removing liquid collection means 6.

The removing liquid supplying means 5 includes a removing liquid supplying opening 5a and a removing liquid supplying unit 5b which supplies removing liquid to the removing liquid supplying opening 5a. In the removing unit 32, the removing liquid supplying opening 5a is provided so as to face the film-formation-unneeded region (e.g., e1) on the substrate 1. When the removing liquid supplying unit 5b is activated, the removing liquid 8 for removing the coated film 2 is supplied to the removing liquid supplying opening 5a by the removing liquid supplying unit 5b, and the removing liquid 8 is discharged onto the substrate 1 from the substrate 1 side opening end of the removing liquid supplying opening 5a. The removing liquid supplying unit 5b is constituted of a syringe pump or the like which is capable of discharge with a constant quantity, and discharges a constant quantity of the removing liquid 8 onto the substrate 1 through the removing liquid supplying opening 5a. The removing liquid collection means 6 is provided with a removing liquid collection opening 6a disposed facing the film-formation-unneeded region (e.g., e1) on the substrate 1, and a removing liquid collection unit 6b. The removing liquid collection opening 6a is disposed, for example, in the vicinity of an end portion in the longitudinal direction of the removing unit 32.

The removing liquid collection unit 6b includes, for example, a suction device, such as an ejector tank. With the activation of the removing liquid collection unit 6b, the removing liquid 8 on the substrate 1 is collected in the removing liquid collection unit 6b via the removing liquid collection opening 6a.

Also, in the bottom surface of the removing unit 32, at least a portion located between the removing liquid supplying opening 5a and the removing liquid collection opening 6a is flat.

As shown in FIG. 8, the coated film removing apparatus 102 is disposed being inclined in the thickness direction (up and down direction in FIG. 8) of the substrate 1 such that the distance h2 between the surface of the substrate 1 on which the coated film 2 is formed and the removing liquid collection opening 6a is shorter than the distance h1 between the surface of the substrate 1 on which the coated film 2 is formed and the removing liquid supplying opening 5a.

As shown in FIG. 8, the coated film removing apparatus 102 is disposed being inclined in the thickness direction of the substrate 1 such that the distance h1 between the surface of the substrate 1 on which the coated film 2 is formed and the removing liquid supplying opening 5a is longer, by 0.1 mm or more, than the distance h2 between the surface of the substrate 1 on which the coated film 2 is formed and the removing liquid collection opening 6a.

In FIG. 8, the removing liquid supplying opening 5a is disposed only at one position in the vicinity of an end portion in the longitudinal direction of the removing unit 32. However, the arrangement of the removing liquid supplying opening 5a is not limited to this. For example, for a positional relationship between the removing liquid supplying opening 5a and the removing liquid collection opening 6a, the above-described distance condition between the coated film removing apparatus 102 and the surface of the substrate 1 may only have to be satisfied. Further, the removing liquid supplying opening 5a and the removing liquid collection opening 6a may each be provided at a plurality of positions.

The removing unit 32 having the above-described configuration activates the removing liquid supplying means 5 and the removing liquid collection means 6 in a state where the moving unit 32a is moved and disposed facing the film-formation-unneeded regions e1 to e4, whereby the removing liquid 8 is ensured to be discharged onto the film-formation-unneeded regions and collected, while being prevented from flowing outside the film-formation-unneeded region.

As shown in FIG. 1 (d), in the case of the moving unit 32b, for example, the removing liquid supplying means 5 and the removing liquid collection means 6 can be activated, while the moving unit 32b is moved and disposed so that the removing unit 32 faces the film-formation-unneeded regions e5 to e7.

(Operations and Other)

Hereinafter, operations of the above-described embodiments will be described.

As shown in FIGS. 1(a)-1(d), the height measurement device 4 measures the distance h between the surface of the substrate 1 and central portion of the moving unit 32a. Then, the height adjustment devices 13 lift up/down and incline the moving unit 32a with respect to the distance h measured by the height measurement device 4, such that the distances h1 and h2 from the both ends of the moving unit 32a to the surface of the substrate 1 become predetermined values.

Thereafter, for example, the moving unit 32a is arranged facing the coated film 2 formed on the substrate 1 so as to be close to each other. Next, the removing liquid 8 is discharged onto the substrate 1 from the removing liquid supplying unit 5b through the removing liquid supplying opening 5a, so as to hold a constant quantity of removing liquid 8 in a gap between the moving unit 32a and the substrate 1 on which the coated film 2 is formed. Then, this condition is maintained for a predetermined period.

Subsequently, similar to the first embodiment, the removing liquid collection unit 6b is activated to collect the removing liquid 8 on the substrate 1 through the removing liquid collection opening 6a.

The distances h1 and h2 set to the above-described setting to values may preferably be set to distances with which the removing liquid 8 between the moving unit 32a and the substrate 1, on which the coated film 2 is coated, is maintained at a constant width depending on characteristics, such as viscosity and surface tension, of the removing liquid 8. Thus, by activating the moving units 32a and 32b, as shown in FIG. 1(d), the coated film 2 only in the film-formation-unneeded regions e1 to e7 of the substrate 1 is removed.

### Example 2

Hereinafter, the present invention will be described in more detail with by way of examples.

### Example 2-1

As an example of a coated film removing apparatus 102 according to the second embodiment, the following description sets forth the case where, in a film formation process of a hole transport layer of an organic EL display, an organic material is coated on the substrate 1 with a slit die to form the hole transport layer, and an unnecessary coated film 2 is removed in an outer periphery of the light emission region in a necessary film-formation range.

As a material of the hole transport layer to be coated, poly (3,4) ethylene dioxy thiophene/polystyrene sulfonic acid (PEDOT/PSS) was used, and as a removing liquid 8, pure water was used.

For the substrate 1, non-alkali glass OA-10 (manufactured by Nippon Electric Glass Co., Ltd), 120 mm×120 mm×0.7 mm was used, and the necessary film-formation range was set to 80 mm×80 mm. Then, an unnecessary coated film 2 formed in the four outer peripheral sides was selectively removed.

First, the above-described hole transport layer material was coated, in a range of 90 mm×90 mm, on a cleaned substrate 1 using a slit die, followed by drying at 180° C. under reduced pressure for an hour, thereby obtaining the coated film 2 with a thickness of 100 nm.

A range of 80 mm×80 mm was assumed as a necessary film-formation region 11 close to the center of a coated range of the hole transport layer material, and the coated film 2 was selectively removed from four outer peripheries of the region using the coated film removing body 3 having the removing liquid supplying means 5 and the removing liquid collection means 6 shown in FIG. 8.

In the coated film removing body 3, the bottom surface of the removing unit 32 had a dimension of 10 mm in the short-side direction and 100 mm in the longitudinal direction.

As the removing liquid supplying unit 5b of the removing liquid supplying means 5, a syringe pump was used to enable constant discharge. Hence, the quantity of the removing liquid 8 held between the substrate 1 and the coated film removing body 3 was appropriately adjusted to avoid overflowing of the removing liquid 8 from the removing unit 32.

Condition shown in table 1 were used for the distance h1 between the surface of the substrate 1 and the removing liquid supplying opening 5a, and the distance h2 between the surface of the substrate 1 and the removing liquid collection opening 6a. The height and the inclination of the coated film removing body 3 were adjusted based on the measurement values of the dial gauges attached to the vicinities of the removing liquid supplying opening 5a and the removing liquid collection opening 6a, to set the distances h1 and h2 to prescribed values.

TABLE 1

| | |
|---|---|
| | distance difference (discharge distance − collection |
| discharge | distance) [mm]/angle |

| distance | 0 | 0.1 | 0.2 | 0.5 | 1.0 | 2.0 |
|---|---|---|---|---|---|---|
| [mm] | 0° | 0.06° | 0.12° | 0.29° | 0.57° | 1.15° |
| 1.0 | (1) | (5) | (9) | (13) | — | — |
| 2.0 | (2) | (6) | (10) | (14) | (17) | — |
| 3.0 | (3) | (7) | (11) | (15) | (18) | (20) |
| 4.0 | (4) | (8) | (12) | (16) | (19) | (21) |

Evaluations based on the above-described distance conditions are shown in tables 2 and 3.

TABLE 2

| | |
|---|---|
| | distance difference (discharge distance − collection |
| discharge | distance) [mm]/angle |

| distance | 0 | 0.1 | 0.2 | 0.5 | 1.0 | 2.0 |
|---|---|---|---|---|---|---|
| [mm] | 0° | 0.06° | 0.12° | 0.29° | 0.57° | 1.15° |
| 1.0 | ⊙ | ⊙ | ⊙ | ⊙ | — | — |
| 2.0 | ⊙ | ⊙ | ⊙ | ⊙ | ⊙ | — |
| 3.0 | ◯ | ◯ | ◯ | ◯ | ◯ | ◯ |
| 4.0 | X | X | X | X | X | X |

State of liquid-film depending on distance: ⊙ very good ◯ good (slightly divergent) X greatly divergent

TABLE 3

| | |
|---|---|
| | distance difference (discharge distance − collection |
| discharge | distance) [mm]/angle |

| distance | 0 | 0.1 | 0.2 | 0.5 | 1.0 | 2.0 |
|---|---|---|---|---|---|---|
| [mm] | 0° | 0.06° | 0.12° | 0.29° | 0.57° | 1.15° |
| 1.0 | X | ◯ | ◯ | ◯ | — | — |
| 2.0 | X | ◯ | ◯ | ◯ | ◯ | — |
| 3.0 | Δ | ◯ | ◯ | ◯ | ◯ | ◯ |
| 4.0 | Δ | ◯ | ◯ | ◯ | ◯ | ◯ |

State of collection of removing liquid: ◯ very good Δ long collection time X liquid remained

Table 2 shows an evaluation on the state of liquid film formed by supplying the removing liquid 8 to a portion between the surface of the substrate 1 and the coated film removing body 3.

As shown in table 2, when the distance between the removing liquid supplying opening 5a and the substrate 1 becomes larger, the substrate 1 side removing liquid 8 wet-spreads, thereby producing a divergent shape. This divergent shape causes residual removing liquid when the removing liquid collection means 6 collects the removing liquid 8. Hence, the removing liquid 8 cannot be collected reliably. Considering the shape of the liquid film of the removing liquid 8, the distance between the removing liquid supplying opening 5a and the surface of the substrate 1 may preferably be set to 3.0 mm or less, more preferably 2.0 mm or less.

Table 3 shows an evaluation on the state of collecting the removing liquid 8 when the liquid film formed by supplying the removing liquid 8 between the surface of the substrate 1 and the coated film removing body 3, is sucked by the ejector tank.

As shown in table 3, regardless of the distance between the surface of the substrate 1 and the removing liquid supplying opening 5a, by setting a difference in the distance from the removing liquid supplying opening 5a and the removing liquid collection opening 6a, to the surface of the substrate 1, the removing liquid 8 can be favorably collected.

However, when the distance difference is small, the collection is slow. Therefore, an appropriate distance difference is needed in view of the time taken for collection. Specifically, favorable distance difference is 0.1 mm or more.

In the present example, a dial gauge was used as the height measurement device 4. The device 4 is not limited to dial gauge. For example, a non-contact measurement device such as a laser displacement meter is preferably used in view of minimizing scratches or foreign materials.

The removing liquid collection means 6 takes exhaust, and collects the removing liquid 8 being held between the substrate 1 and the coated film removing body 3 for a desired period and dissolving the hole transport layer material. It should be noted that almost all coated film 2 was removed with the holding time of 30 seconds or more. Moreover, repeating the same operation once more, remaining material which has not yet been collected can reliably be collected so that more favorable cleanness will be possible.

As described above, the coated film removing body 3 repeatedly scanned the substrate, changing a scanning direction by 90 degrees, and the unnecessary coated film was successively removed in the film-formation-unneeded region formed of four outer sides of the necessary film-formation range. Hence, remaining coated film was disappeared in the outer periphery of the necessary film-formation range of 80 mm×80 mm, and a desired condition was confirmed where no removing liquid 8 splashed into the necessary film-formation range.

### Example 2-2

In the example 2-1, the temperature condition of the removing liquid 8 was 24° C. at the condition shown in (5) of the table 1. However, according to the Example 2-2, the temperature condition of the removing liquid 8 was changed to 30° C. from 24° C., and similarly, the coated film 2 was removed. For conditions other than the temperature condition of the removing liquid 8, the same condition as the example 2-1 was used.

As a result, comparing with the case where the coated film 2 was removed in about 30 seconds when the temperature of the removing liquid 8 was 24° C., the period required for removing the coated film 2 was shortened to approximately 20 seconds, when the temperature of the removing liquid 8 was 30° C. Hence, the removal performance was significantly improved. When the temperature of the removing liquid 8 was increased more, the removal performance was further improved.

However, when increasing the temperature higher than 40° C., a gain in the removal performance is limited so that effect is not significant. Moreover, on the other hand, an influence of steam will be a concern. Accordingly, when the temperature condition is determined, consideration is required for the apparatus and materials to be used.

### Example 2-3

According to the example 2-3, the coated film 2 was removed by the coated film removing body 3 under the conditions of the example 2-2, i.e., under the condition (5) in table 1 of example 2-1, with the temperature condition of the removing liquid 8 being 30° C., and with an ultrasonic oscillator as the ultrasonic vibration application unit 14 applying ultrasonic vibration to the removing liquid 8. The output power of the ultrasonic vibration was set to around 50 to 300 watts and the oscillation frequency was set to around 30 to 100 KHz.

As a result, comparing with the case where the coated film 2 was removed in about 20 seconds without applying ultrasonic vibration, the time taken for removing the coated film 2 was shortened to approximately 15 seconds by applying ultrasonic vibration. Hence, the removing performance was confirmed to be significantly improved.

Thus, the coated film 2 can reliably be removed from an outer peripheral portion of an organic light emission pixel. This enables production of an organic EL panel in which a simple coating method of uniformly forming a film is applied to a film-formation of a common layer, such as a hole transport layer and a hole injection layer, without the necessity of conducting coating on a pixel basis.

As described, examples 2-1 to 2-3 have been described so far. However, the present invention is not limited to the above-described examples. As described, examples of the organic EL display have been described. However, the present invention is not limited to these examples, but may be applied to a film formation substrate for other purposes such as liquid crystal color filters similar to the above-described first embodiment.

Also, the coated film 2 is not limited to a material used for an organic EL such as the hole transport layer, but may be applied to materials for other purposes such as photosensitive resist or the like.

The removing liquid 8 can be appropriately selected depending on the material of the coated film 2, for example, alkali developing liquid, organic solvents and etchants or the like can be the candidates of the selection.

### Third Embodiment

With reference to the drawings, hereinafter, a coated film removing apparatus 103 according to a third embodiment of the present invention will be described.

(Overall configuration of coated film removing apparatus 103) FIGS. 1(a)-1(d) are overall configurations showing the coated film removing apparatus 103 according to the third embodiment of the present invention. FIG. 2 is a perspective view showing an operation example of the coated film removing apparatus 103 according to the third embodiment of the present invention. In FIG. 1(d), descriptions of the removing liquid supplying opening 5a and the removing liquid collection openings 6a according to the third embodiment are omitted. As shown in FIGS. 1(a)-1(d), the configuration of the coated film removing apparatus 103 is approximately the same as the configuration of the coated film removing apparatus 102 according to the second embodiment. That is, the coated film removing apparatus 103 is provided with a coated film removing body 3, a stage 10 that chucks and holds the substrate 1 having a coated film 2 to be removed, and a height adjustment device 13. Similar to the second embodiment, the coated film removing body 3 according to the third embodiment is provided with a moving unit 33a and a moving unit 33b.

Similar to the second embodiment, the moving units 33a and 33b according to the third embodiment each include a removing unit 33. However, the removing units 33 according to the third embodiment is different from the removing unit 32 according to the second embodiment in the cross-sectional structure taken along the Ba-Bb line shown in FIG. 1 (d) (See FIG. 9).

Therefore, in the third embodiment, a structure of the removing unit 33 will be mainly described, omitting explanation on portions substantially the same as those of the above-described embodiments. Also, explanations of the operations and processes substantially the same as those described in the above-described embodiments will be omitted.

(Configuration of Removing Unit 33)

FIG. 9 is an example of a cross sectional view showing the removing unit 33 shown in FIG. 1 (d) taken along a line Ba-Bb. As shown in FIG. 9, the removing unit 33 is provided with a removing liquid supplying means 5 and a removing liquid collection means 6 and removing liquid detecting means 5c and 6c.

The removing liquid supplying means 5 includes a removing liquid supplying opening 5a and a removing liquid supplying unit 5b which supplies removing liquid to the removing liquid supplying opening 5a. The removing liquid supplying unit 5b according to the third embodiment is configured of a discharge pump which can be either a non-volume pump or a volume pump. Considering errors due to a time-lag when the device is stopped after detecting the removing liquid or opening/closing of valve or the like, the removing liquid supplying unit 5b may preferably be configured such that the discharge rate is adjustable.

Moreover, if removal is successively conducted and constant quantity discharge is achieved such as by a volume pump, a required discharge quantity can vary, depending on the degree of accuracy in height adjustment or the degree of surface tension viscosity of the removing liquid 8. Hence, it is preferable to control the supply quantity on the basis of the detection results derived from the removing liquid detecting means 5c and 6c, so as to prevent excessive supply or insufficient supply.

A control device 15 as a control unit receives a signal when the removing liquid 8 has been detected by both the removing liquid detecting means 5c and 6c. Based on the detection signal, the control device 15 outputs a supply stop signal in respect of the removing liquid 8 and stops supply.

The removing liquid detecting means 5c and 6c may be provided at least at two positions corresponding to both ends of the device, i.e. in the vicinities of the removing liquid supplying opening 5a and the removing liquid collection openings 6a. However, to confirm a state of liquid flow, the removing liquid detecting means 5c and 6c may be provided at two or more positions.

Generally, an infrared reflecting reflector or the like is used for the removing liquid detecting means 5c and 6c. It is not limited to these devices. However, any device can be used as long as the device is capable of detecting removing liquid.

The removing liquid collection means 6 is provided with a removing liquid collection opening 6a disposed facing the film-formation-unneeded region (e.g., e1) on the substrate 1 and a removing liquid collection unit 6b. The removing liquid collection opening 6a is disposed, for example, in the vicinity of an end portion in the longitudinal direction of the removing unit 33.

The removing liquid collection unit 6b includes, for example, a suction device such as a pump and an ejector tank. With the activation of the removing liquid collection unit 6b, the removing liquid 8 on the substrate 1 is collected in the removing liquid collection unit 6b via the removing liquid collection opening 6a.

The control device 15 controls the ejector to collect the removing liquid through the removing liquid collection opening 6a until a removing liquid detection signal detected by the removing liquid detecting means 5c and 6c is released. Then, the control device 15 issues a command to stop collecting the removing liquid 8, when a signal indicating absence of removing liquid is received.

The collection quantity of the removing liquid 8 may be constant using a constant volume pump and a timer control. However, it is preferable that presence of the removing liquid 8 is confirmed by the removing liquid detecting means 5c and 6c. Thus, the position of the removing liquid 8 can be determined, preventing the removing liquid 8 from remaining in the device or preventing excessive suction of the removing liquid 8 reaching the removing liquid supplying opening 5a. Hence, non-uniformity is avoided in successively removing the liquid.

(Operations and Others)

Hereinafter, operations of the above-described embodiments will be described.

As shown in FIGS. 1(a)-1(d), the height measurement device 4 measures the distance h between the surface of the substrate 1 and a central portion of the moving unit 33a.

Then, the height adjustment device 13 lifts up/down and inclines the moving unit 33a with respect to the distance h measured by the height measurement device 4 such that the distances h1 and h2 from the unit to the surface of the substrate 1, at both ends of the moving unit 33a, become predetermined values.

Thereafter, for example, the moving unit 33a is arranged facing the coated film 2 formed on the substrate 1 so as to be close to each other. Next, the removing liquid 8 is discharged onto the substrate 1 from the removing liquid supplying unit 5b through the removing liquid is supplying opening 5a, so as to hold a constant quantity of the removing liquid 8 in the gap between the moving unit 33a and the substrate 1 on which the coated film 2 is formed.

Then, after the removing liquid detecting means 5c and 6c have detected the removing liquid 8, discharge of the liquid is stopped, and this state is maintained for a predetermined period.

Subsequently, similar to the above-described embodiments, the removing liquid 8 on the substrate 1 is collected by the removing liquid collection means 6.

Specifically, the control device 15 activates the removing liquid collection unit 6b so as to collect the removing liquid 8 on the substrate 1 through the removing liquid collection opening 6a. As for a collection period, the control device 15 stops the collection, after confirming the signal of the removing liquid detecting means 5c and 6c indicating detection of the removing liquid has been turned OFF.

Thus, by activating the moving units 33a and 33b, as shown in FIG. 1(d), only the coated film 2 in the film-formation-unneeded regions e1 to e7 of the substrate 1 is removed.

### Example 3

Hereinafter, the present invention will be described in more detail by way of examples.

### Example 3-1

As an example of a coated film removing apparatus 103 according to a third embodiment, the following description sets forth the case where, in a film formation process of a hole transport layer of an organic EL display, an organic material is coated on the substrate 1 with a slit die to form a hole transport layer, and an unnecessary coated film 2 is removed in an outer periphery of the light emission region in a necessary film-formation range.

As a hole transport layer material to be coated, poly (3,4) ethylene dioxy thiophene/polystyrene sulfonic acid (PEDOT/PSS) was used, and as the removing liquid 8, pure water was used.

For the substrate 1, non-alkali glass OA-10 (manufactured by Nippon Electric Glass Co., Ltd), 120 mm×120 mm×0.7 mm was used, and the necessary film-formation range was set to 80 mm×80 mm. Then, an unnecessary coated film 2 formed in the four outer peripheral sides was selectively removed.

First, the above-described hole transport layer material was coated, in a range of 90 mm×90 mm, on a cleaned substrate 1 using a slit die, followed by drying at 180° C. under a reduced pressure for an hour, thereby obtaining the coated film 2 with a thickness of 100 nm.

A range of 80 mm×80 mm was assumed as a necessary film-formation region 11 close to the center of a coated range of the hole transport layer material, and the coated film 2 was selectively removed from four outer peripheries of the region using the coated film removing body 3 having the removing liquid supplying means 5 and the removing liquid collection means 6 shown in FIG. 9.

In the coated film removing body 3, the bottom surface of the removing unit 33 had a dimension of 10 mm in the short-side direction and 100 mm in the longitudinal direction.

As the removing liquid detecting means 5c and 6c, single-point infrared sensors were installed inside the removing liquid supplying opening 5a, and inside the removing liquid collection opening 6a. Assuming a change in the liquid quantity due to opening/closing of the valves of the removing liquid supplying unit 5b and the removing liquid collection unit 6b, sensors may better be provided inside the removing liquid supplying opening 5a and the removing liquid collection opening 6a to avoid excessive liquid quantity. The number of sensors is not limited to one for supply and one for collection, but several sensors may be provided to observe transitional state of the removing liquid 8.

As the removing liquid supplying unit 5b of the removing liquid supplying means 5, a syringe pump was used to discharge the removing liquid 8 until both of the removing liquid detecting means 5c and 6c detect the removing liquid 8 held in a gap between the substrate 1 and the coated film removing apparatus 103, and output a signal. The control device 15 stops supplying the removing liquid 8 upon reception of the detection signal, and maintains this state for a predetermined period.

Conditions shown in table 4 were used for the distance h1 with respect to the bottom surface of the removing liquid supplying opening 5a of the coated film removing body 3, and the distance h2 with respect to the removing liquid collection opening 6a side bottom surface of the coated film removing body 3. A supply gap corresponds to the distance h1 and a collection gap corresponds to the distance h2. The height and the inclination of the coated film removing body 3 were adjusted based on the measurement values of the dial gauges attached to the vicinities of the removing liquid supplying opening 5a and the removing liquid collection opening 6a of the coated film removing body 3, to set the distances h1 and h2 to prescribed values. Conditions of the supply gap and difference between the supply gap and the collection gap are shown in Table 4.

TABLE 4

| | |
|---|---|
| | gap difference (supply gap − collection gap) |
| supply | [mm]/angle |

| gap | 0 | 0.1 | 0.2 | 0.5 | 1.0 | 2.0 |
|---|---|---|---|---|---|---|
| [mm] | 0° | 0.05° | 0.11° | 0.29° | 0.57° | 1.15° |
| 1.0 | (1) | (5) | (9) | (13) | — | — |
| 2.0 | (2) | (6) | (10) | (14) | (17) | — |
| 3.0 | (3) | (7) | (11) | (15) | (18) | (20) |
| 4.0 | (4) | (8) | (12) | (16) | (19) | (21) |

Evaluations on the above-described gap conditions are shown in tables 5 and 6.

TABLE 5

| | |
|---|---|
| | gap difference (supply gap − collection gap) |
| supply | [mm]/angle |

| gap | 0 | 0.1 | 0.2 | 0.5 | 1.0 | 2.0 |
|---|---|---|---|---|---|---|
| [mm] | 0° | 0.05° | 0.11° | 0.29° | 0.57° | 1.15° |
| 1.0 | ⊙ | ⊙ | ⊙ | ⊙ | — | — |
| 2.0 | ⊙ | ⊙ | ⊙ | ⊙ | ⊙ | — |
| 3.0 | ◯ | ◯ | ◯ | ◯ | ◯ | ◯ |
| 4.0 | X | X | X | X | X | X |

Liquid-film shape in gap: ⊙ very good ◯ good (slightly divergent shape) X greately divergent shape

TABLE 6

| | |
|---|---|
| | gap difference (supply gap − collection gap) |
| supply | [mm]/angle |

| gap | 0 | 0.1 | 0.2 | 0.5 | 1.0 | 2.0 |
|---|---|---|---|---|---|---|
| [mm] | 0° | 0.05° | 0.11° | 0.29° | 0.57° | 1.15° |
| 1.0 | X | ◯ | ◯ | ◯ | — | — |
| 2.0 | X | ◯ | ◯ | ◯ | ◯ | — |
| 3.0 | Δ | ◯ | ◯ | ◯ | ◯ | ◯ |
| 4.0 | Δ | ◯ | ◯ | ◯ | ◯ | ◯ |

State of collection of removing liquid: ◯ very good Δ long collection time X liquid remained

Table 5 shows an evaluation on the liquid film shape when the removing liquid 8 is supplied to a gap between the surface of the substrate 1 and the bottom surface of the coated film removing body 3 to form a liquid film. As the gap with respect to the surface of the substrate 1 at the removing liquid supplying opening 5a becomes larger, the removing liquid 8 of the substrate 1 side wet-spreads more, thereby producing a divergent shape. This divergent shape causes the removing liquid to remain when the removing liquid collection means 6 collects the removing liquid. Hence, the removing liquid 8 cannot be collected reliably.

Considering the shape of the liquid film of the removing liquid 8, as will be seen from table 5, the gap with respect to the surface of the substrate 1 at the removing liquid supplying opening 5a is preferably set to 3.0 mm or less, more preferably 2.0 mm or less.

Table 6 shows an evaluation on a state of collecting the removing liquid 8 when the liquid film formed by supplying the removing liquid 8 between the surface of the substrate 1 and the bottom surface of the coated film removing body 3 is sucked by the ejector tank. Regardless of the gap between the surface of the substrate 1 and the removing liquid supplying opening 5a, the removing liquid 8 can be favorably collected by setting a difference in a dimension of the gap with respect to the surface of the substrate 1, at the removing liquid supplying opening 5a and the removing liquid collection opening 6a.

However, when the gap difference is small, the collection is slow so that an appropriate gap difference is needed in view of the time required for collection. Specifically, favorable gap difference is 0.1 mm or more.

In the present example, a dial gauge was used as the height measurement device 4. The device 4 is not limited to dial gauge. For example, a non-contact measurement device such as a laser displacement meter is preferably used in view of minimizing scratches or foreign materials.

The removing liquid collection means 6 takes exhaust, and collects the removing liquid 8 being held between the substrate 1 and the coated film removing body 3 for a desired period and dissolving the hole transport layer material. It should be noted that almost all coated film 2 was removed with the holding time of 30 seconds or more.

Moreover, repeating the same operation once more, remaining material which has not yet been collected can reliably be collected so that more favorable cleanness will be possible.

As described above, the coated film removing body 3 repeatedly scanned the substrate, changing a scanning direction by 90 degrees, and the unnecessary coated film was successively removed in the film-formation-unneeded region formed of four outer sides of the necessary film-formation range. Hence, remaining coated film was removed in the outer periphery of the necessary film-formation range of 80 mm×80 mm, and a desired condition was confirmed where no removing liquid 8 splashed into the necessary film-formation range.

### Example 3-2

In example 3-2, of the conditions shown in (5) of table 4 of the example 3-1, conditions except the temperature condition of the removing liquid 8 were unchanged, and the coated film 2 was removed similarly. The result was shown in table 7.

TABLE 7

| temperature (° C.) | removal time (second) |
|---|---|
| 24 | 30 |
| 30 | 20 |
| 40 | 19 |

As can be seen from table 7, comparing with the case where the coated film 2 was removed in about 30 seconds when the temperature of the removing liquid 8 was 24° C., the period required for removing the coated film 2 was shortened to approximately 20 seconds when the temperature of the removing liquid 8 was 30° C. Hence, the removal performance was confirmed to be significantly improved. When the temperature of the removing liquid 8 was increased more, the removal performance was confirmed to be further improved. However, when the temperature is set higher than 40° C., a gain in the removal performance is limited and the effect of the temperature is not significant. On the other hand, an adverse effect of steam is a concern. Therefore, when the temperature condition is determined, the apparatus and materials are needed to be taken care accordingly.

Thus, the coated film 2 can reliably be removed from an outer peripheral portion of an organic light emission pixel. This enables production of an organic EL panel in which a simple coating method of uniformly forming a film is applied to a film-formation of a common layer, such as a hole transport layer and a hole injection layer, without the necessity of conducting coating on a pixel basis.

As described, examples 3-1 to 3-2 have been described so far. However, the present invention is not limited to these examples. As described, examples of the organic EL display have been described. However, it is not limited to these examples, but the above examples may be applied to a film formation substrate for other purposes such as liquid crystal color filters similar to the above-described first embodiment.

Also, the coated film 2 is not limited to a material used for an organic EL such as the hole transport layer, but may be applied to materials for other purposes such as photosensitive resist or the like.

The removing liquid 8 can be appropriately selected depending on the material of the coated film 2, for example, alkali developing liquid, organic solvent and etchant or the like can be selected.

### Fourth Embodiment

With reference to the drawings, hereinafter, a coated film removing apparatus 104 according to the fourth embodiment of the to present invention will be described.

(Overall Configuration of Coated Film Removing Apparatus 104)

FIGS. 1(a)-1(d) are overall configurations showing the coated film removing apparatus 104 according to the fourth embodiment of the present invention. FIG. 2 is a perspective view showing an operation example of the coated film removing apparatus 104 according to the forth embodiment of the present invention. In FIG. 1(d), descriptions of the removing liquid supplying opening 5a and the removing liquid collection openings 6a according to the fourth embodiment are omitted.

As shown in FIGS. 1(a)-1(d), the configuration of the coated film removing apparatus 104 is approximately the same as the configuration of the coated film removing apparatus 101 to 103 according to the first to third embodiments. That is, the coated film removing apparatus 104 is provided with a coated film removing body 3, a stage 10 that chucks and holds the substrate 1 having a coated film 2 to be removed, and a height adjustment device 13. Similar to the above-described embodiments, the coated film removing body 3 according to the fourth embodiment is provided with a moving unit 34a and a moving unit 34b.

The height adjustment device 13 according to the fourth embodiment serves as a gap-dimension adjustment device capable of changing distances h1 and h2 individually, where h1 is a distance between the bottom surface 19 of the removing liquid supplying opening 5a side moving units 34a and 34b and the surface of the substrate 1, and h2 is a distance between the removing liquid collection opening 6a side bottom surface 19 and the surface of the substrate 1.

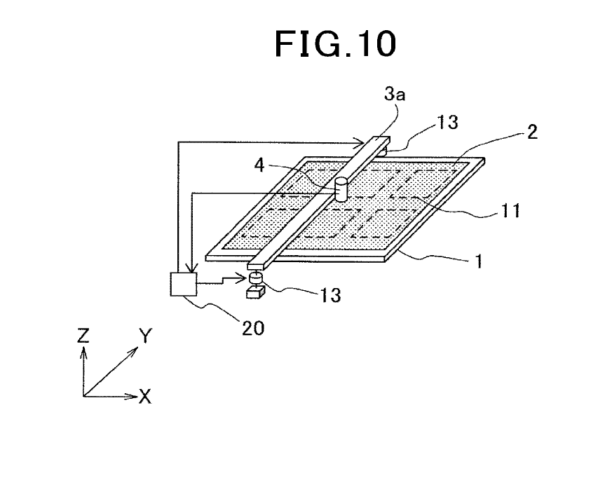

The coated film removing apparatus 104 is different from the coated film removing apparatuses 101 to 103 (see FIG. 10) in that the to apparatus 104 includes a control unit 20. Therefore, the fourth embodiment is described focusing on the control unit 20, and description is omitted for portions substantially the same as those of the above-described embodiments. Also, description of the operations and processes substantially the same as those described in the above-described embodiments is also omitted.

(Configuration of Control Unit 20)

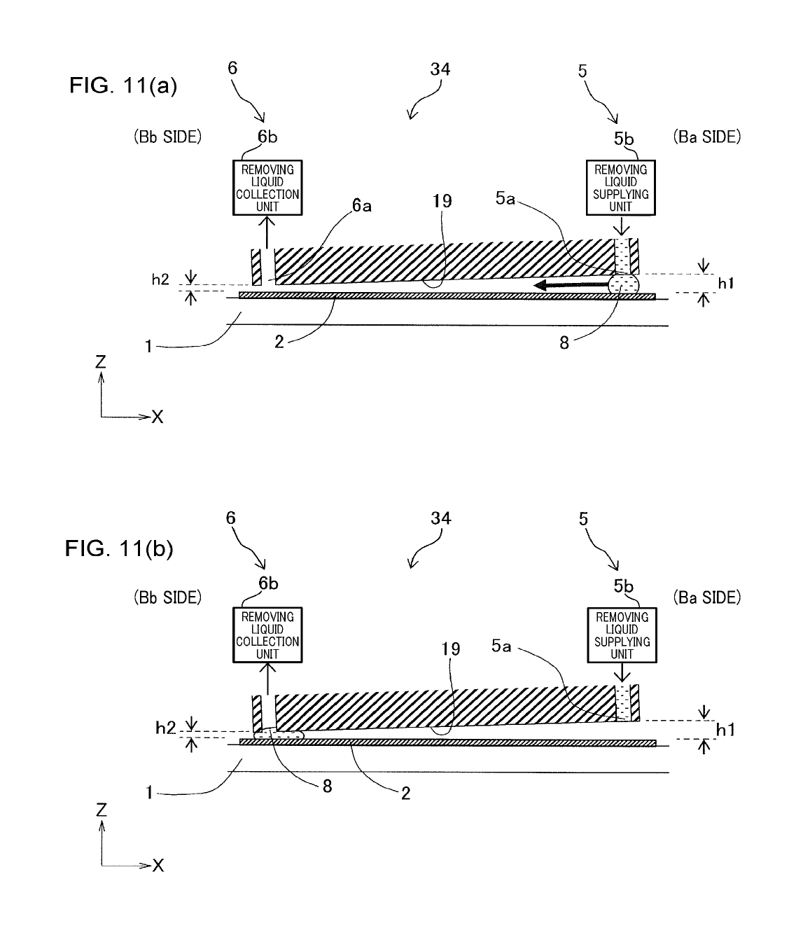

FIG. 10 is a perspective view showing an operation example of the coated film removing apparatus 104 according to the fourth embodiment. FIGS. 11(a)-11(b) are exemplary cross sectional views, showing a removing unit 34 shown in FIG. 1(d), taken along a line Ba-Bb.

As shown in FIGS. 10, 11(a) and 11(b), the control unit 20 adjusts the bottom surface 19 of the coated film removing apparatus 104, using the height adjustment device 13, such that the bottom surface 19 is inclined by 0.05 degrees or more with respect to the surface of the substrate 1, in a direction in which the bottom surface 19 and the substrate 1 face with each other, when the removing liquid 8 is present at least between the bottom surface 19 of the coated film removing apparatus 104 and the surface of the substrate 1. The bottom surface 19 refers to a bottom surface located between the removing liquid supplying opening 5a and the removing liquid collection opening 6a.

The control unit 20 preferably adjusts the gap between the bottom surface 19 and the substrate 1 to 3.0 mm or less via the height adjustment device 13, when the removing liquid 8 is present at least between the bottom surface 19 and the surface of the substrate 1.

The control unit 20 preferably changes, one or more times, the inclination of the bottom surface 19 with respect to the surface of the substrate 1 via the height adjustment device 13, when the removing liquid 8 is present at least between the bottom surface 19 and the surface of the substrate 1.

Moreover, the control unit 20 preferably further includes a height measurement device 4 that measures a distance between the surface of the substrate 1 and the bottom surface 19, and preferably adjust the gap between the surface of the substrate 1 and the bottom surface 19 according to the measurement value of the height measurement device 4, via the height adjustment device 13.

The control unit 20 is preferably provided with a first processing unit, a second processing unit, and a third processing unit. The first processing unit sets the distance h1 to be relatively larger than the distance h2 before the removing liquid 8 is supplied from the removing liquid supplying opening 5a, where the distance h1 is a distance between the bottom surface 19 of the removing liquid supplying opening 5a side and the surface of the substrate 1, and the distance h2 is a distance between the removing liquid collection opening 6a side bottom surface 19 and the surface of the substrate 1. The second processing unit alternately changes the inclination of the bottom surface 19 with respect to the surface of the substrate 1 for a predetermined number of times, when it is determined that the removing liquid 8 has been discharged from the removing liquid supplying opening 5a. The third processing unit sets the distance h1 to be relatively smaller than the distance h2 when it is determined that the removing liquid 8 is collected from the removing liquid collection opening 6a, where the distance h1 is a distance between the removing liquid supplying opening 5a side bottom surface 19 and the surface of the substrate 1, and the distance h2 is a distance between the removing liquid collection opening 6a side bottom surface 19 and the surface of the substrate 1.

Similar to the above-described embodiments, the removing liquid supplying unit 5b is constituted of a syringe pump or the like which is capable of discharge with a constant quantity. Also, according to the fourth embodiment, a constant quantity of removing liquid 8 is discharged, in the form of droplets, onto the substrate 1 via the removing liquid supplying opening 5a by using the removing liquid supplying unit 5b.

(Operations and Other)

Hereinafter, operations of the above-described embodiments will be described.

As shown in FIGS. 1(a)-1(d), the height measurement device 4 measures the distance h between the surface of the substrate 1 and a central portion of the moving unit 34a. Then, the height adjustment device 13 lifts up/down and inclines the moving unit 34a with respect to the distance h measured by the height measurement device 4 such that the distances h1 and h2 between the unit and the surface of the substrate 1 at both ends of the moving unit 34a become predetermined values.

Thereafter, for example, the moving unit 34a is arranged facing the coated film 2 formed on the substrate 1 so as to be close to each other. Next, the removing liquid 8 is discharged, in the form of droplets, onto the substrate 1 from the removing liquid supplying unit 5b through the removing liquid supplying opening 5a, so as to hold a constant quantity of the removing liquid 8 in the gap between the moving unit 34a and the substrate 1 on which the coated film 2 is formed.

The distances h1 and h2 set to the above-described setting values are preferably a distance (3 mm or less) with which droplets of the removing liquid 8 are maintained at a constant width, according to characteristics, such as viscosity and surface tension, of the removing liquid 8 which is present between the moving unit 34a and the substrate 1 on which coated film 2 is coated.

At this time, the discharged removing liquid 8 in the form of droplets moves towards a portion having a narrower gap dimension h2 from a portion having a wider gap dimension h1.

The removing liquid 8 reaches the removing liquid collection opening 6a and, after lapse of a prescribed time, conversely, the height of the removing liquid supplying opening 5a is decreased to h2 and the height of the removing liquid collection opening 6a is increased to h1, whereby the removing liquid 8 further flows in the width direction (X-axis direction) of the coated film removing apparatus 104, so as to improve solubility and a releasability of the unnecessary coated film. In this case, the heights of the removing liquid supplying opening 5a and the removing liquid collection opening 6a are not defined by predetermined heights h1 and h2. However, both heights are not necessary the same, and may be alternately changed like a seesaw to have an inclination.

These operations are repeatedly performed to change the heights. When a predetermined period is elapsed by which the coated film 2 is estimated to be dissolved or peeled off, the removing liquid collection means 6 collects and drains the removing liquid 8 which has been mixed with the coated film 2 between the moving unit 34a and the substrate 1. In other words, the removing liquid collection unit 6b is to activated so as to collect the removing liquid 8 on the substrate 1 through the removing liquid collection opening 6a.

Thus, the coated film 2 in the film-formation-unneeded regions e1 to e7 on the substrate 1 is removed so that a completely clean surface of the substrate 1 can be obtained. Compared to a method in which the removing liquid 8 is discharged to make a liquid film, and after leaving the film for a constant period of time, the removing liquid 8 is collected, the quantity of the removing liquid can be reduced.

Thus, by activating the moving units 34a and 34b, as shown in FIG. 1(d), only the coated film 2 in the film-formation-unneeded regions e1 to e7 of the substrate 1 is removed.

The process of collecting removing liquid according to the fourth embodiment is the same as the process in the above-described embodiments.

### Example 4

The present invention will be described in more detail by way of examples.

### Example 4-1

As an example of the coated film removing apparatus 104 according to the fourth embodiment, the following description sets forth the case where, in a film formation process of a hole transport layer of an organic EL display, an organic material is coated on the substrate 1 with a slit die to form the hole transport layer, and the unnecessary coated film 2 is removed from an outer periphery of the light emission region which is a necessary film-formation range.

As a hole transport layer material to be coated, poly (3,4) ethylene dioxy thiophene/polystyrene sulfonic acid (PEDOT/PSS) was used, and as the removing liquid 8, pure water was used.

For the substrate 1, non-alkali glass OA-10 (manufactured by Nippon Electric Glass Co., Ltd), 120 mm×120 mm×0.7 mm was used, and the necessary film-formation range was set to 80 mm×80 mm. Then, an unnecessary coated film 2 formed in the four outer peripheral sides were selectively removed.

First, the above-described hole transport layer material was coated, in a range of 90 mm×90 mm, on a cleaned substrate 1 using a slit die, followed by drying at 180° C. under a reduced pressure for an hour, thereby obtaining the coated film 2 with a thickness of 100 nm. A range of 80 mm×80 mm was assumed as a necessary film-formation region 11 close to the center of a coated range of the hole transport layer material, and the coated film 2 was selectively removed for four outer periphery sides thereof using the coated film removing body 3 having the removing liquid supplying means 5 and the removing liquid collection means 6 shown in FIGS. 11(a)-11(b).

As the coated film removing body 3, a body was used in which a dimension of the bottom surface of the removing unit 34 is, 10 mm of the short direction and 100 mm of the longitudinal direction.

A syringe pump capable of discharge with a constant quantity was used for the removing liquid supplying unit 5b of the removing liquid supplying means 5, and the discharge quantity was adjusted to 0.4 ml such that the removing liquid 8 held in a gap between the substrate 1 and the coated film removing body 3 becomes droplets.

Conditions shown in table 8 was used for the distance h1 with respect to the lower end of the removing liquid supplying opening 5a of the coated film removing body 3, and the distance h2 with respect to the lower end of the removing liquid collection opening 6a. The height and the inclination of the coated film removing body 3 were adjusted based on each of the measurement values of the dial gauges attached to the vicinities of the removing liquid supplying opening 5a and the removing liquid collection opening 6a of the coated film removing body 3, to set the distances h1 and h2 to prescribed values. After discharging the droplets from the removing liquid supplying opening 5a, heights of the distances h1 and h2 were switched so as to move the droplets. Then, the distances of the removing liquid supplying opening 5a and the removing liquid collection opening 6a were set back to h1 and h2 again. Thereafter, the removing liquid 8 was collected.

TABLE 8

| | |
|---|---|
| | gap difference (supply gap − collection gap) |
| supply | [mm]/angle |

| gap | 0 | 0.1 | 0.2 | 0.5 | 1.0 | 2.0 |
|---|---|---|---|---|---|---|
| [mm] | 0° | 0.05° | 0.12° | 0.29° | 0.57° | 1.15° |
| 1.0 | (1) | (5) | (9) | (13) | — | — |
| 2.0 | (2) | (6) | (10) | (14) | (17) | — |
| 3.0 | (3) | (7) | (11) | (15) | (18) | (20) |
| 4.0 | (4) | (8) | (12) | (16) | (19) | (21) |

Evaluations of the above-described gap conditions are shown in tables 9 and 10.

TABLE 9

| | |
|---|---|
| | gap difference (supply gap − collection gap) |
| supply | [mm]/angle |

| gap | 0 | 0.1 | 0.2 | 0.5 | 1.0 | 2.0 |
|---|---|---|---|---|---|---|
| [mm] | 0° | 0.05° | 0.12° | 0.29° | 0.57° | 1.15° |
| 1.0 | X | ◯ | ◯ | ◯ | — | — |
| 2.0 | X | ◯ | ◯ | ◯ | ◯ | — |
| 3.0 | X | ◯ | ◯ | ◯ | ◯ | ◯ |
| 4.0 | X | ◯ | ◯ | ◯ | ◯ | ◯ |

detergency: ◯ good X bad

TABLE 10

| | |
|---|---|
| | gap difference (supply gap − collection gap) |
| supply | [mm]/angle |

| gap | 0 | 0.1 | 0.2 | 0.5 | 1.0 | 2.0 |
|---|---|---|---|---|---|---|
| [mm] | 0° | 0.05° | 0.12° | 0.29° | 0.57° | 1.15° |
| 1.0 | ⊙ | ⊙ | ⊙ | ⊙ | — | — |
| 2.0 | ⊙ | ⊙ | ⊙ | ⊙ | ⊙ | — |
| 3.0 | ◯ | ◯ | ◯ | ◯ | ◯ | ◯ |
| 4.0 | X | X | X | X | X | X |

liquid-film shape in gap: ⊙ very good ◯ good (slight divergent shape) X large divergent shape

The table 9 is an evaluation result of a collection state of the removing liquid 8 in which the liquid film formed by supplying the removing liquid 8 in a gap between the surface of the substrate 1 and the coated film removing body 3, is suctioned by the ejector tank. Regardless of the gap between the surface of the substrate 1 and the removing liquid supplying opening 5a, by setting a difference in a distance of the gap with respect to the surface of the substrate 1 at the removing liquid supplying opening 5a and the removing liquid collection opening 6a, the removing liquid 8 can be favorably collected.

However, when the difference in the gap is small, the collection time is slow so that appropriate distance difference is required considering the required collection time. Specifically, a favorable condition is 0.1 mm or more.

The table 10 is an evaluation result of the liquid film shape in which the removing liquid 8 is supplied to a gap between the surface of the substrate 1 and the bottom surface of the coated film removing body 3 to form a liquid film. As shown in Table 10, when the gap with respect to the surface of the substrate 1 at the removing liquid supplying opening 5a becomes larger, the removing liquid 8 of the substrate 1 side spreads out, thereby producing a divergent shape. This divergent shape causes a residue of the removing liquid when the removing liquid collection means 6 collects the removing liquid. Hence, the removing liquid 8 cannot be collected reliably. Considering the shape of the liquid film of the removing liquid 8, the gap with respect to the surface of the substrate 1 at the removing liquid supplying opening 5a may preferably be set to 3.0 mm or less, more preferably, 2.0 mm or less.

In the present example, a dial gauge as the height measurement device 4 was used. It is not limited to this dial gauge. However, a non-contact measurement device such as a laser displacement meter may preferably be used in view of suppressing scratches or foreign material.

The removing liquid collection means 6 takes exhaust, and collects the removing liquid 8 being held between the substrate 1 and the coated film removing body 3 for a desired period and dissolving the hole transport layer material. It should be noted that almost all coated film 2 was removed with the holding time of 30 seconds or more. Moreover, repeating the same operation once more, remaining material which has not yet been collected can reliably be collected so that more favorable cleanness will be possible.

The coated film removing body 3 repeatedly scanned the substrate, changing a scanning direction by 90 degrees, and the unnecessary coated film was successively removed in the film-formation-unneeded region formed of four outer sides of the necessary film-formation range. Hence, remaining coated film was disappeared in the outer periphery of the necessary film-formation range of 80 mm×80 mm, and a desired condition was confirmed where no removing liquid 8 splashed into the necessary film-formation range.

### Example 4-2

In the example 4-1, the temperature condition of the removing liquid 8 was 24° C. at the condition shown in (5) of the table 8 in the example 4-1. However, according to the example 4-2, the temperature condition of the removing liquid 8 was changed to 30° C. from 24° C., and similarly, the coated film 2 was removed. For conditions other than the temperature condition of the removing liquid 8, the same condition as the example 4-1 was used.

As a result, comparing with the case where the coated film 2 was removed in about 30 seconds when the temperature of the removing liquid 8 was 24° C., the period required for removing the coated film 2 was shortened to approximately 20 seconds, when the temperature of the removing liquid 8 was 30° C. Hence, the removal performance was significantly improved. When the temperature of the removing liquid 8 was increased more, the removal performance was further improved.

However, when increasing the temperature higher than 40° C., a gain in the removal performance is limited so that effect is not significant. Moreover, on the other hand, an influence of steam will be a concern. Accordingly, when the temperature condition is determined, consideration is required for the apparatus and materials to be used.

Thus, the coated film 2 can reliably be removed in an outer peripheral portion of organic light emission pixel so that an organic EL panel can be produced, in which a coating method simply forming with uniformity is applied to a film-formation of the common layer which requires no separate-coating for each pixel of the hole transport layer and the hole injection layer or the like.

As described, examples 4-1 to 4-2 have been described so far. However, the present invention is not limited to these examples. As described, examples of the organic EL display have been described. However, it is not limited to these examples, but the above examples may be applied to a film formation substrate for other purposes such as liquid crystal color filters similar to the above-described first embodiment.

Also, the coated film 2 is not limited to a material used for an organic EL such as the hole transport layer, but may be applied to materials for other purposes such as photosensitive resist or the like.

The removing liquid can be appropriately selected depending on the material of the coated film, for example, alkali developing liquid, organic solvent and etchant or the like can be selected.

### Fifth Embodiment

With reference to the drawings, hereinafter, a coated film removing apparatus 105 according to the fifth embodiment of the present invention will be described.

(Overall Configuration of Coated Film Removing Apparatus 105)

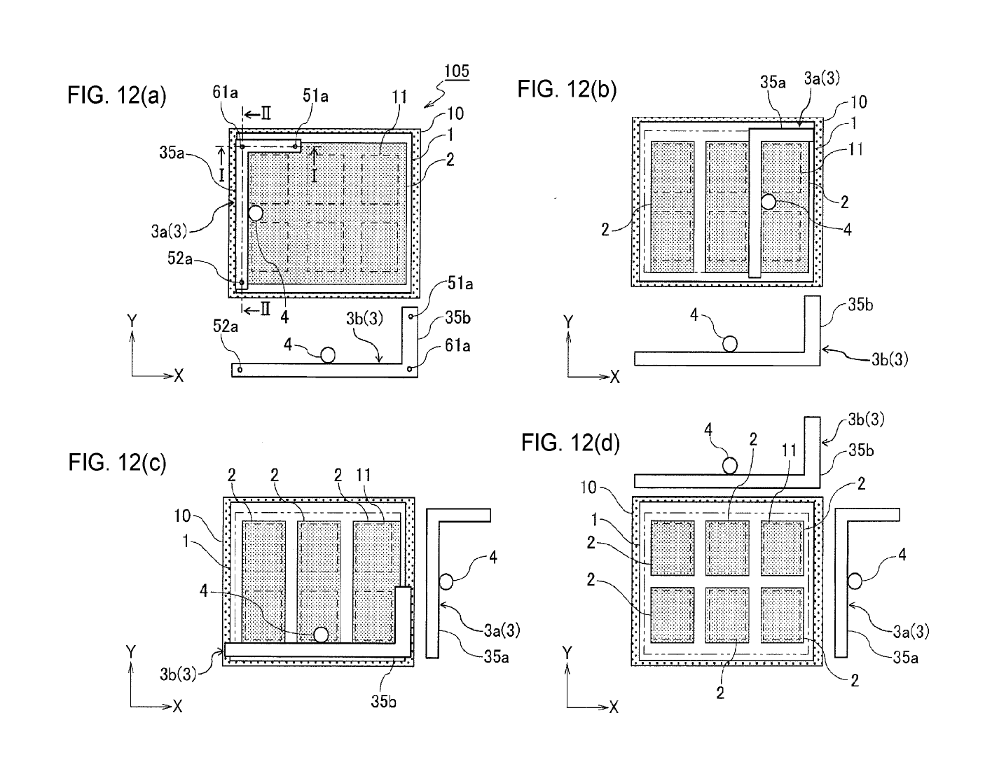

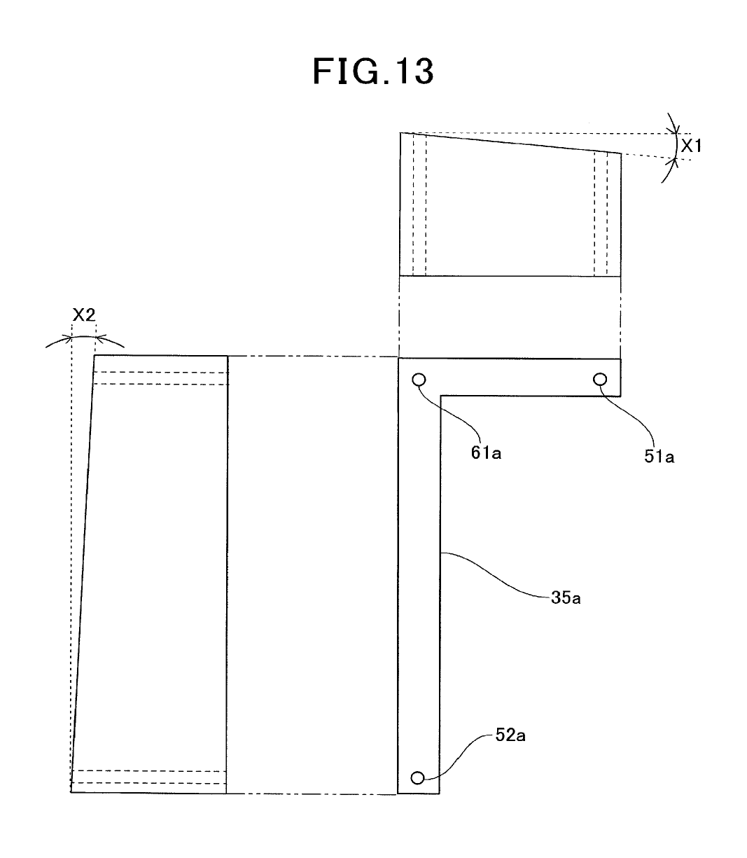

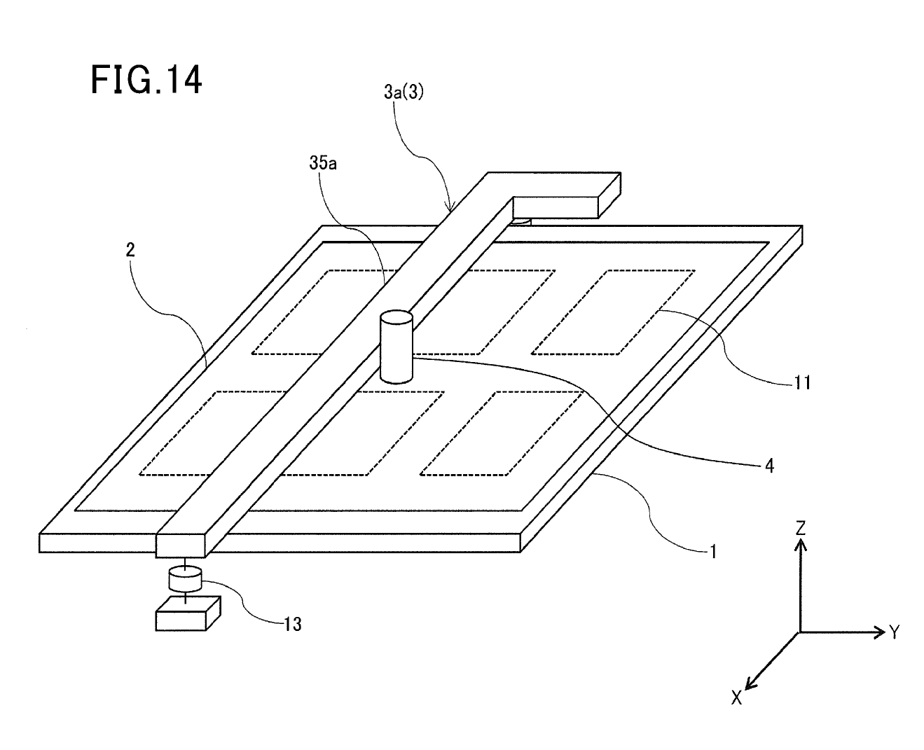

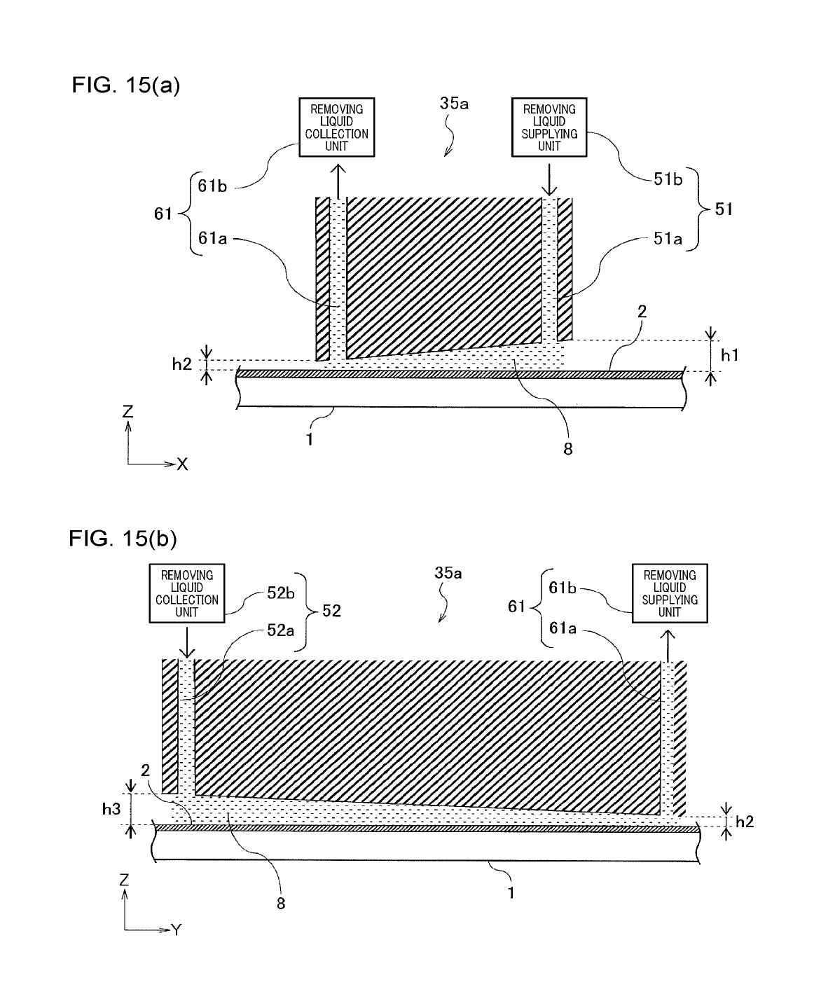

FIGS. 12(a)-12(d) are plan views showing a configuration of a coated film removing apparatus according to the fifth embodiment. FIG. 13 is a diagram of a front view, a plan view and a side view, showing a coated film removing apparatus according to the fifth embodiment. FIG. 14 is a perspective view showing an operation example of the coated film removing apparatus according to the fifth embodiment. FIGS. 15(a)-15(b) are cross sectional views showing a configuration of the coated film removing apparatus according to the fifth embodiment.

As shown in FIG. 12 (a) and FIG. 14, the coated film removing apparatus 105 is provided with a coated film removing body 3, a stage 10 that chucks and holds the substrate 1 having a coated film to be removed, a height measurement device 4 and a height adjustment device 13. The coated film removing body 3 is provided with a moving unit 35a and a moving unit 35b. As shown in FIG. 12 (a), the moving unit 35a moves along the X-axis direction of the stage 10 and removes a coated film 2 formed on the substrate 1 in the X-direction and the Y-direction, and the moving unit 35b moves along the Y-axis direction of the stage 10 and removes a coated film 2 formed on the substrate 1 in the Y-direction and the X-direction.

The moving unit 35a is disposed along the Y-axis direction of the stage 10, bridging over the substrate 1 chucked and held on the stage 10 in the Y-axis direction. The necessary film-formation regions 11 are formed in a lattice pattern. Hence, as shown in FIG. 12 (a), FIG. 13 and FIG. 14, the surface shape of the moving unit 35a (planar shape) has L-shape that orthogonally crosses the X-axis direction and the Y-axis direction, being in parallel to the X-axis direction and the Y-axis direction in the X-Y plane. In other words, in the necessary film-formation region 11 having a rectangular shape, two sides among four sides of the necessary film-formation region can be simultaneously removed.

As shown in FIG. 15 (a) and FIG. 15 (b), the moving unit 35a is provided with a removing liquid supplying means 51 and 52, and a removing liquid collection means 61. The removing liquid supplying means 51 and 52 have removing liquid supplying openings 51a and 52a respectively, and also have removing liquid supplying units 51b and 52b respectively, which supplies the removing liquid 8 to the removing liquid supplying openings 51a and 52a. The removing liquid collection means 61 is provided with a removing liquid collection opening 61a, and a removing liquid collection unit 61b that collects the removing liquid 8 via a removing liquid collection opening 61a. The removing liquid supplying openings 51a and 52a are provided in the vicinity of the end portions of respective edges which orthogonally cross in the L-shape of the moving unit 35a. The removing liquid collection opening 61a is provided in the vicinity of a corner portion in the L-shape of the moving unit 35a. The removing liquid supplying openings 51a and 52a, and the removing liquid collection opening 61a are provided to face the substrate 1 and penetrate through the removing unit 35 in the Z-axis direction.

As shown in FIG. 13, the removing liquid supplying openings 51a and the removing liquid collection opening 61a are provided to have an inclination of an angle X1 formed between respective openings of the removing liquid supplying openings 51a and the removing liquid collection opening 61a at the bottom surface side (Z-axis negative direction side shown in FIG. 14) of the moving unit 35a. Further, the removing liquid supplying openings 52a and the removing liquid collection opening 61a are provided to have an inclination of an angle X2 at the bottom surface side of the moving unit 35a.

These inclinations of the bottom surface of the removing unit 35 are provided through whole bottom surface of the moving unit 35a. In other words, in the L-shaped moving unit 35a, the bottom surface of the short side edge extending in the X-axis direction has an inclination of X1 with respect to X-Y plane in the X-axis direction, and the bottom surface of the long side edge extending in the Y-axis direction has an inclination of X2 with respect to X-Y plane in the Y-axis direction.

As shown in FIG. 15 (a), the angle X1 is set such that the distance h2 is shorter than the distance h1, where the distance h1 is formed between the bottom surface of a side end portion in the positive Y-axis direction of the moving unit 35a and the surface of the substrate 1 on which the coated film 2 is coated, and the distance h2 is formed between the bottom surface of a side end portion in the negative Y-axis direction of the moving unit 35a and the surface of the substrate 1 on which the coated film 2 is coated.

Similarly, the angle X2 is set such that the distance h3 is shorter than the distance h2, where the distance h3 is formed between the bottom surface of a side end portion in the positive X-axis direction of the moving unit 35a and the surface of the substrate 1 on which the coated film 2 is coated, and the distance h2 is formed between the bottom surface of a side end portion in the negative X-axis direction of the moving unit 35a and the surface of the substrate 1 on which the coated film 2 is coated.

The removing liquid supplying units 51b and 52b are constituted of a syringe pump or the like which is capable of discharging with constant quantity, and discharges a constant quantity of the removing liquid 8 onto the substrate 1 through the removing liquid supplying openings 51a and 52a. Also, the removing liquid collection unit 61b includes a suction device such as ejector tank, and by operating the removing liquid collection unit 61b, the removing liquid 8 on the substrate 1 is collected in the removing liquid collection unit 61b via the removing liquid collection opening 61a. The moving unit 35a, by operating the removing liquid supplying units 51b and 52b, supplies the removing liquid 8 from the removing liquid supplying units 51b and 52b to the removing liquid supplying openings 51a and 52a, and discharges the removing liquid 8 onto the substrate 1 from the opening end of the substrate 1 side of the removing liquid supplying openings 51a and 52a. Also, the moving unit 35a collects the removing liquid 8 being discharged from the removing liquid supplying units 51b and 52b from the removing liquid collection opening 61a, by operating the removing liquid collecting unit 61b.

The height measurement device 4 is supported by the side end portion in the positive X-axis direction located at the center portion in the Y-axis direction of the moving unit 35a, and measures the distance h between the surface of the substrate 1 and a bottom surface of the X-axis center portion of the moving unit 35a.

The height adjustment device 13 is provided at both end portions in the Y-axis direction of the moving unit 35a, and controls, based on the distance h measured by the height measurement device 4, the moving unit 35a to lift or down such that the distances h2 and h3 with respect to the surface of the substrate 1 at the both end portions in the Y-axis direction of the moving unit 35a become prescribed values set in advance.

Similar to the moving units 31a to 34a according to the above-described embodiments, the moving unit 35a moves in the X-axis direction and the Z-axis direction, for example, by a guide and a lifting mechanism (both are not shown) disposed at both ends of the Y-axis direction of the stage 10, extending in the X-axis direction. Thus, for example, as shown in FIGS. 14, 15(a) and 15(b), the moving unit 35a moves in the X-axis direction, maintaining a prescribed distance h between the surface of the substrate 1 and the moving unit 35a. According to the fifth embodiment, the lifting mechanism constitutes the height adjustment device 13. The lifting mechanism may be provided at both ends of a linear section along the Y-axis direction in the moving unit 35a so as to constitute the height adjustment device 13.

The moving unit 35b is formed to have a shape in which the L-shape thereof in the X-Y plane is inverted with respect to the moving unit 35a. Other configurations are the same as configurations in the moving unit 35a. As shown in FIG. 12 (a), the moving unit 35a is formed such that in the X-Y plane, the long side edge extends in the negative Y-axis direction from the L-shaped corner portion, and the short side edge extends in the positive X-axis direction from the corner portion of the L-shape. However, the moving unit 35b is formed such that in the X-Y plane, the long side edge extends in the negative X-axis direction from the L-shaped corner portion, and the short side edge extends in the positive Y-axis direction from the corner portion of the L-shape.

According to the fifth embodiment, the necessary film-formation regions 11 each having a rectangular shape are formed in a lattice pattern. To fit this shape, the moving unit 35b is arranged in a direction inverted from the moving unit 35a, in plan view. The moving unit 35b is disposed along the X-axis direction of the stage 10, bridging over the substrate 1 chucked and held on the stage 10. Then, when removing the coated film, the height adjustment device 13 supporting the moving unit 35b controls, based on the distance h measured by the height measurement device 4 fixed to the moving unit 35a, the moving unit 35b to lift or down such that the distances h1 and h2 between the surface of the substrate 1 and the moving unit 35b become a prescribed value set in advance. The moving unit 35b moves in the Y-axis direction and the Z-axis direction, for example, by a guide and a lifting mechanism (neither are shown) disposed at both end of the X-axis direction of the stage 10, extending in the Y-axis direction. Thus, the moving unit 35b scans the substrate 1 in the Y-axis direction thereof. In other words, the moving units 35a and 35b may be movable in two directions of the X-axis direction and the Y-axis direction.

The lifting mechanism according to the present embodiment is similar to the lifting mechanism of the above-described embodiments.

The moving units 35a and 35b move along the substrate 1 by a drive unit which is not shown. The moving units 35a and 35b move along the substrate 1 to be located above the film-formation-unneeded regions, and removes coated film 2 corresponding to the film-formation-unneeded regions e1 to e7.

FIG. 12 (b) illustrates a state where the moving unit 35a has successively moved to positions corresponding to a part of the film-formation-unneeded regions e3 and e4. Also, FIG. 12 (d) illustrates a state where the film-formation-unneeded regions e1 to e7 are removed by the moving units 35a and 35b.

A removing process of the coated film 2 using the moving units 35a and 35b is the same as the removing process of the coated film 2 described in the above embodiments. The moving units 35a and 35b have the same configuration. However, the distances h1 and h2 between the surface of the substrate 1 and the moving units 35a and 35b can be set to different distances.

Thus, the coated film removing body 3 according to the fifth embodiment operates the removing liquid supplying means 51 and 52, the removing liquid collection means 61 in a state where the removing unit 35 is moved to face the film-formation-unneeded regions e1 to e7, whereby the removing liquid 8 is prevented from flowing outside the film-formation-unneeded regions e1 to e7, the removing liquid 8 is discharged onto the film-formation-unneeded regions e1 to e7, and the removing liquid 8 is collected.

### (Operations and Other)

Hereinafter, operations of the above-described embodiments will be described.

As shown in FIG. 12 (a), the height measurement device 4 measures distance h between the surface of the substrate 1 and the central portion of the moving unit 35a. Then, the height adjustment device 13 lifts the moving unit 35a with respect to the distance h measured by the height measurement device 4 such that the distances h1 and h2 between the both ends in the Y-axis direction of the moving unit 35a and the surface of the substrate 1 become predetermined values.

The distances h1 and h2 may preferably be set to distance where the removing liquid 8 between the moving unit 35a and the substrate 1 on which the coated film 2 is coated is maintained at a constant width depending on characteristics of a viscosity and a surface tension of the removing liquid 8.

Next, for example, the moving unit 35a is arranged to face the coated film 2 formed on the substrate 1, being close to each other. Next, the removing liquid 8 is discharged onto the substrate 1 from the removing liquid supplying units 51b and 52b through the removing liquid supplying openings 51a and 52a, so as to hold a constant quantity of removing liquid 8 in the gap between the moving unit 35a and the substrate 1 on which the coated film 2 is formed. Then, this condition is held for a predetermined period. The predetermined period is sufficient time for the removing liquid 8 to dissolve or peel off the coated film 2.

Further, the removing liquid 8 is held on the film-formation-unneeded regions e1 to e7 for a predetermined period, whereby the coated film 2 is dissolved or peeled off. When a predetermined period is elapsed at which the coated film 2 is estimated to be dissolved or peeled off, the removing liquid collection unit 61b collects and drains the removing liquid 8 being mixed with the coated film 2 between the moving unit 35a and the substrate 1. In other words, the removing liquid collection unit 61b is operated so as to collect the removing liquid 8 on the substrate 1 through the removing liquid collection opening 61a.

These processes, i.e., supplying and collecting the removing liquid 8 are repeatedly performed, whereby the coated film 2 being present in the film-formation-unneeded regions e1 to e7 on the substrate 1 is removed. Hence, a completely clean surface of the substrate can be obtained.

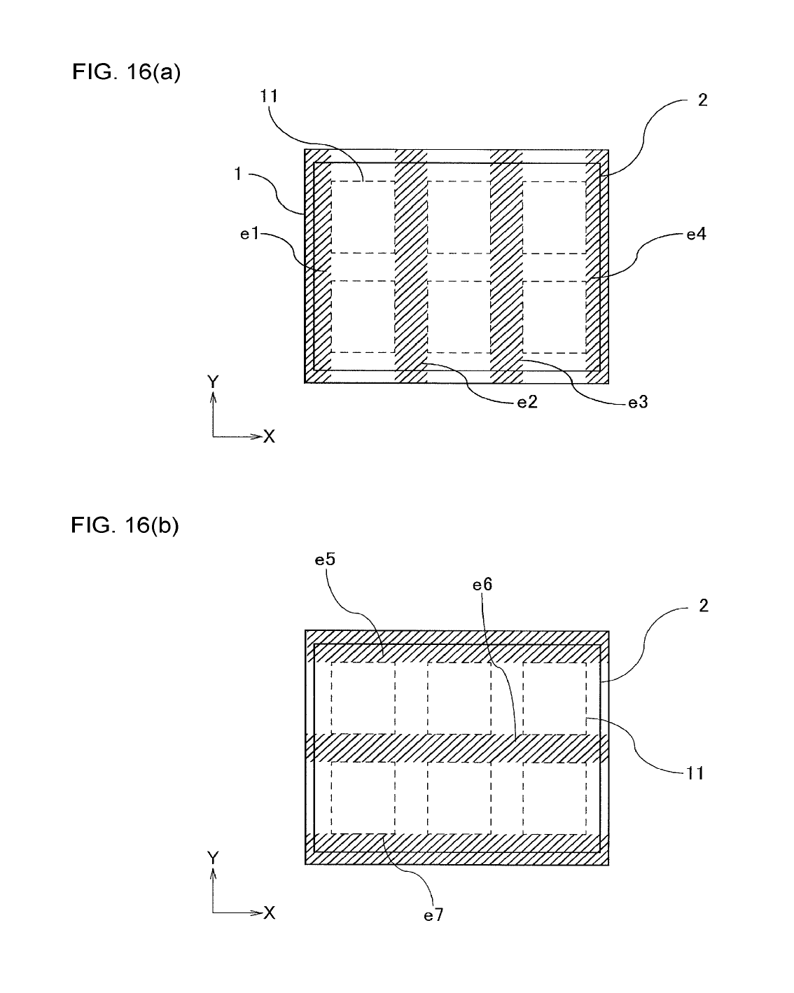

Then, as shown in FIG. 12 (a) and FIG. 12 (b), these operations are performed in respective positions by the moving unit 35a being moved in left-right direction. Thus, moving unit 35a completes to remove the coated film 2 in the film-formation-unneeded regions e1 to e4 extending in the front-back direction of the substrate 1 (See FIGS. 16(a)-16(b)).

Next, as shown in FIG. 12 (c), while the moving unit 35b moves in the Y-axis direction, in the respective positions, the coated film 2 in the film-formation-unneeded regions e5 to e7 of the substrate 1 is removed by similar processes.

Thus, allowing the moving units 35a and 35b to operate, as shown in FIG. 12 (d), the coated film 2 is removed only for the film-formation-unneeded regions e1 to e7 of the substrate 1. Also, the temperature of the discharged removing liquid 8 is set within a range from 30° C. to 40° C., whereby the coated film 2 can be effectively dissolved. As a result, processing time can be shortened and the coated film 2 can be reliably removed.

(Modification)

As described, with reference to the drawings, preferred embodiments of the present invention have been described. However, the present invention is not limited to those examples. A person having ordinary skill in the art to which the present invention pertains apparently arrives various modifications or correction examples without departing the technical ideas described in scope of claims. Hence, it is understood that those modifications or examples apparently belong to the technical scope of the present invention.

For example, according to the above-described embodiments, to the removing liquid supplying openings 51a and 52a are arranged at the end portions of the removing unit 35, and the removing liquid collection opening 61a is arranged at a corner portion of the removing unit 35. However, the positions and the number of openings for the removing liquid supplying openings 51a and 52a and the removing liquid collection opening 61a are not limited to the above-described examples.

Specifically, as long as condition of the gap between the bottom surface of the removing unit 35 and the surface of the substrate 1 is satisfied, for example, a plurality of openings may be provided at positions different from that of FIG. 13. Moreover, the angle X1 and the angle X2 may be set to be different from each other.

The height measurement device 4 may not be fixed to the removing unit 35 of the moving unit 35a, but fixed to the removing unit 35 of the moving unit 35b. Moreover, for example, the height measurement device 4 may be configured to move in the X-axis direction by using a guide (not shown) arranged at both ends of the Y-axis direction of the stage 10, extending in the X-axis direction, thereby independently scanning in the X-axis direction. Similarly, the height measurement device 4 may be configured to move in the Y-axis direction by using a guide (not shown) arranged at both ends of the X-axis direction of the stage 10, extending in the Y-axis direction, thereby independently scanning in the Y-axis direction. In short, the height measurement device 4 may be configured such that the distance h between the removing unit 35 of the moving units 35a and 35b and the surface (surface of the coated film) of the substrate 1 is measured, and the height adjustment device 13 adjusts, based on the measured value, the distances h1 and h2 with respect to the surface of the substrate 1 to be within the prescribed value.

The removing liquid supplying units 51b and 52b and the removing liquid collection unit 61b may be provided separately from the removing unit 35, and the removing liquid supplying unit 51b may be connected to the removing liquid supplying opening 51a via a removing liquid supplying tube capable of being deformed. Similarly, the removing liquid supplying unit 52b may be connected to the removing liquid supplying opening 52a via a removing liquid collecting tube capable of being deformed, and the removing liquid collection unit 61b may be connected to the removing liquid collection opening 61a via the removing liquid collecting tube. These removing liquid supplying units 51b and 52b and the removing liquid collection unit 61b may be provided separately from the coated film removing body 3.

According to the above-described embodiments, the removing unit 35 has an L-shape in the X-Y plane. However, it is not limited to this example. For example, a shape which extends in either the X-axis or the Y-axis direction may be used. In this case, the removing liquid supplying means 51 and 52, and the removing liquid collection means 61 may be provided at each location around the both ends in the longitudinal direction.

### Example 5

The present invention will be described in more detail by way of examples.

### Example 5-1

As an example of the coated film removing apparatus 105 according to the fifth embodiment, the following description sets forth the case where, in a film formation process of a hole transport layer of an organic EL display, an organic material is coated on the substrate 1 with a slit die to form the hole transport layer, and the unnecessary coated film 2 is removed from an outer periphery of the light emission region which is a necessary film-formation range.

As a hole transport layer material to be coated, poly (3,4) ethylene dioxy thiophene/polystyrene sulfonic acid (PEDOT/PSS) was used, and as the removing liquid 8, pure water was used.

For the substrate 1, non-alkali glass OA-10 (manufactured by Nippon Electric Glass Co., Ltd), 120 mm×120 mm×0.7 mm was used, and the necessary film-formation range was set to 80 mm×80 mm. Then, an unnecessary coated film 2 formed in the four outer peripheral sides were selectively removed.

First, the above-described hole transport layer material was coated, in a range of 90 mm×90 mm, on a cleaned substrate 1 using a slit die, followed by drying at 180° C. under a reduced pressure for an hour, thereby obtaining the coated film 2 with a thickness of 100 nm.

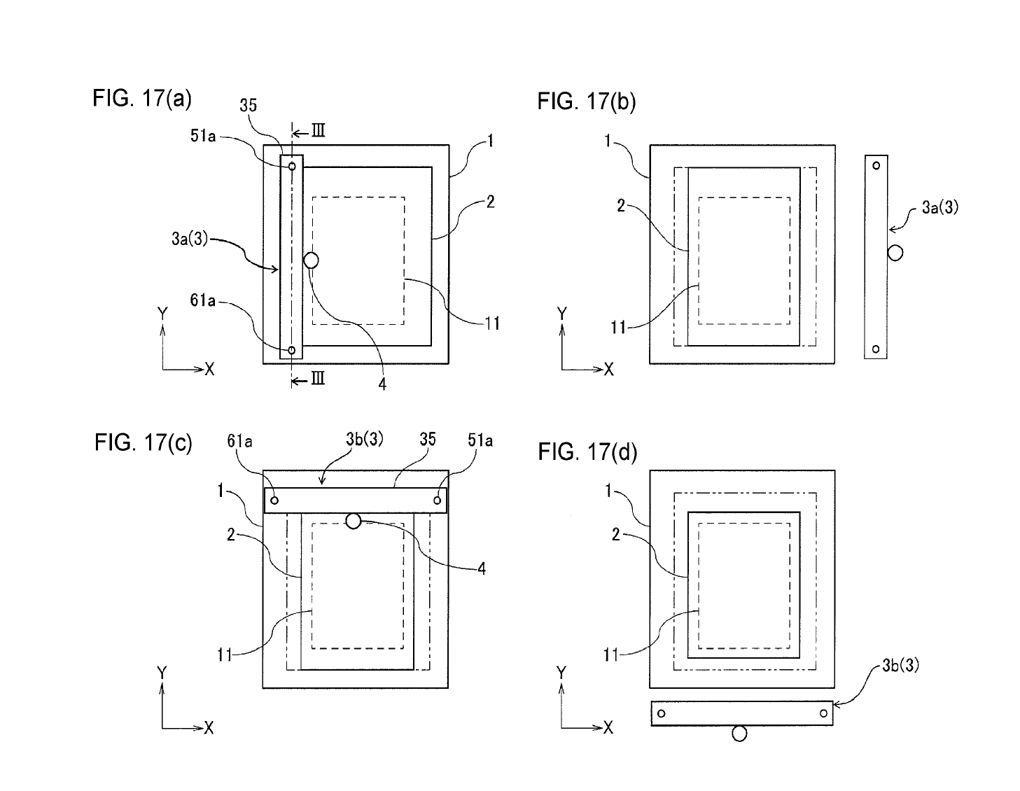

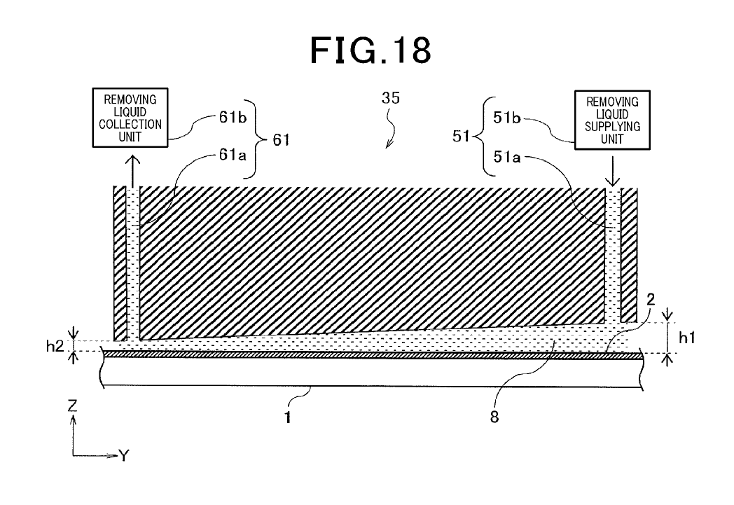

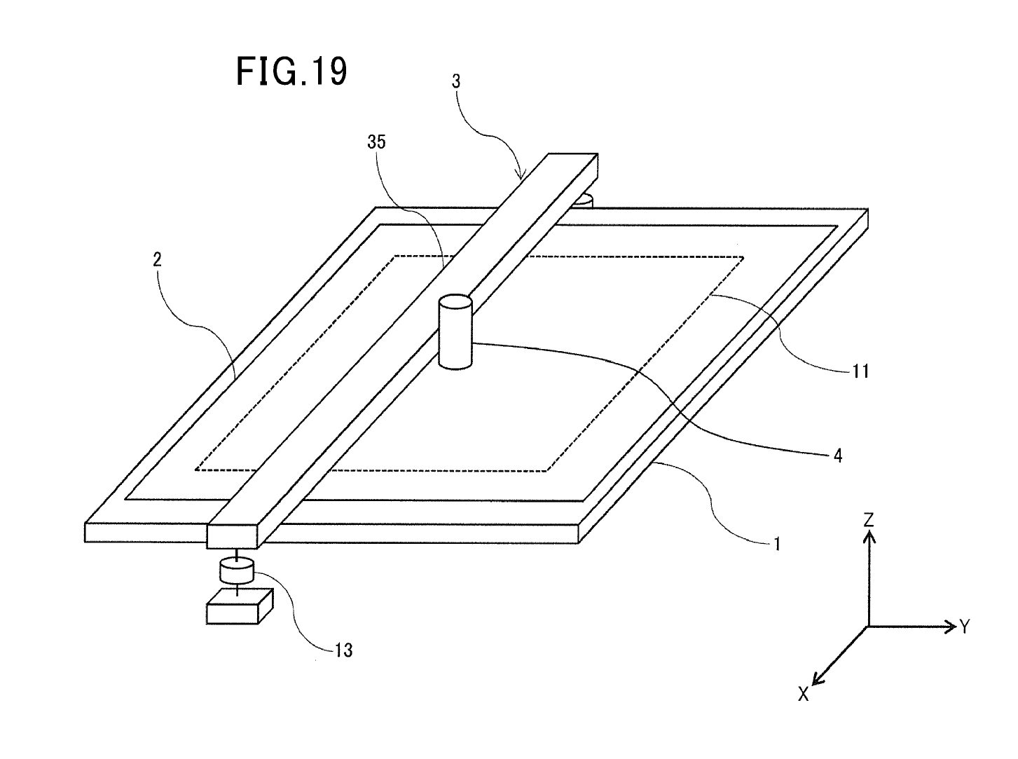

A range of 80 mm×80 mm was assumed as a necessary film-formation region 11 close to the center of a coated range of the hole transport layer material, and the coated film 2 was selectively removed for four outer peripheral sides thereof using the coated film removing body 3. The coated film removing body 3 according to the present embodiment is provided with a removing unit 35 that extends in one direction. As shown in FIG. 17 (a), the removing unit 35 has a removing liquid supplying opening 51a and a removing liquid collection opening 61a located at respective both ends in the longitudinal direction thereof. Above the removing liquid supplying opening 51a and the removing liquid collection opening 61a (positive Z-axis direction side), for example, as shown in FIG. 18, the removing liquid supplying unit 51b and the removing liquid collection unit 61b are provided respectively to form the removing liquid supplying means 51 and the removing liquid collection means 61. The dimensions of the removing unit 35 are 10 mm in the short side direction, and 100 mm in the longitudinal direction. A syringe pump was used for the removing liquid supplying unit 51b of the removing liquid supplying means 51, enabling a constant discharging, whereby the quantity of the removing liquid 8 being held between the substrate 1 and the coated film removing body 3 was appropriately adjusted to avoid overflowing of the removing liquid 8 from the removing unit 35.

A condition described in the table 11 was used for the distance h1 between the surface of the substrate 1 and the lower end of the removing liquid supplying opening 51a of the coated film removing body 3, and the distance h2 with respect to the lower end of the removing liquid collection opening 61a.

The height and the inclination of the coated film removing body 3 was adjusted based on each of the measurement values of the dial gauge attached to the vicinity of the removing liquid supplying opening 51a and the removing liquid collection opening 61a of the coated film removing body 3, to set the distances h1 and h2 to be a prescribed value.

TABLE 11

| | |
|---|---|
| | gap difference (supply gap − collection gap) |
| supply | [mm]/angle |

| gap | 0 | 0.1 | 0.2 | 0.5 | 1.0 | 2.0 |
|---|---|---|---|---|---|---|
| [mm] | 0° | 0.06° | 0.12° | 0.29° | 0.57° | 1.15° |
| 1.0 | (1) | (5) | (9) | (13) | — | — |
| 2.0 | (2) | (6) | (10) | (14) | (17) | — |
| 3.0 | (3) | (7) | (11) | (15) | (18) | (20) |
| 4.0 | (4) | (8) | (12) | (16) | (19) | (21) |

The evaluation result of the above-described gap condition is shown in the tables 12 and 13 as follows.

TABLE 12

| | |
|---|---|
| | gap difference (supply gap − collection gap) |
| supply | [mm]/angle |

| gap | 0 | 0.1 | 0.2 | 0.5 | 1.0 | 2.0 |
|---|---|---|---|---|---|---|
| [mm] | 0° | 0.06° | 0.12° | 0.29° | 0.57° | 1.15° |
| 1.0 | ⊙ | ⊙ | ⊙ | ⊙ | — | — |
| 2.0 | ⊙ | ⊙ | ⊙ | ⊙ | ⊙ | — |
| 3.0 | ◯ | ◯ | ◯ | ◯ | ◯ | ◯ |
| 4.0 | X | X | X | X | X | X |

liquid-film shape in gap: ⊙ very good ◯ good (slight divergent shape) X large divergent shape

TABLE 13

| | |
|---|---|
| | gap difference (supply gap − collection gap) |
| supply | [mm]/angle |

| gap | 0 | 0.1 | 0.2 | 0.5 | 1.0 | 2.0 |
|---|---|---|---|---|---|---|
| [mm] | 0° | 0.06° | 0.12° | 0.29° | 0.57° | 1.15° |
| 1.0 | X | ◯ | ◯ | ◯ | — | — |
| 2.0 | X | ◯ | ◯ | ◯ | ◯ | — |
| 3.0 | Δ | ◯ | ◯ | ◯ | ◯ | ◯ |
| 4.0 | Δ | ◯ | ◯ | ◯ | ◯ | ◯ |

collection state of removing liquid: ◯ very good Δ long collection time X liquid remained

The table 12 is an evaluation result of the liquid film shape in which the removing liquid 8 is supplied to a gap between the surface of the substrate 1 and the coated film removing body 3 to form a liquid film. When the gap between the removing liquid supplying opening 51a and the surface of the substrate 1 becomes larger, the removing liquid 8 of the substrate 1 side spreads out, thereby producing divergent shape. This divergent shape causes a residue of the removing liquid when the removing liquid collection means 61 collects the removing liquid. Hence, the removing liquid cannot be collected reliably. Considering the shape of the liquid film of the removing liquid 8, the gap between the removing liquid supplying opening 51a and the surface of the substrate 1 may preferably be set to 3.0 mm or less, more preferably 2.0 mm or less.

The table 13 is an evaluation result of a collection state of the removing liquid 8 in which the liquid film formed by supplying the removing liquid 8 to a gap between the surface of the substrate 1 and the coated film removing body 3, is suctioned by the ejector tank.

Regardless of the distance between the surface of the substrate 1 and the removing liquid supplying opening 51a, by setting difference in the gap between removing liquid supplying opening 51a and the removing liquid collection opening 61a, and the surface of the substrate 1, the removing liquid 8 can be favorably collected.

However, when the gap difference is small, the collection time is slow so that appropriate gap difference is required considering the required collection time. Specifically, a favorable condition is 0.1 mm or more.

In the present example, a dial gauge as the height measurement device 4 was used. It is not limited to this dial gauge. However, a non-contact measurement device such as a laser displacement meter may preferably be used in view of suppressing scratches or foreign material.

The removing liquid collection means 61 takes exhaust, and collects the removing liquid 8 being held between the substrate 1 and the coated film removing body 3 for a desired period and dissolving the hole transport layer material. It should be noted that almost all coated film 2 was removed with the holding time of 30 seconds or more. Moreover, repeating the same operation once more, remaining material which has not yet been collected can reliably be collected so that more favorable cleanness will be possible.

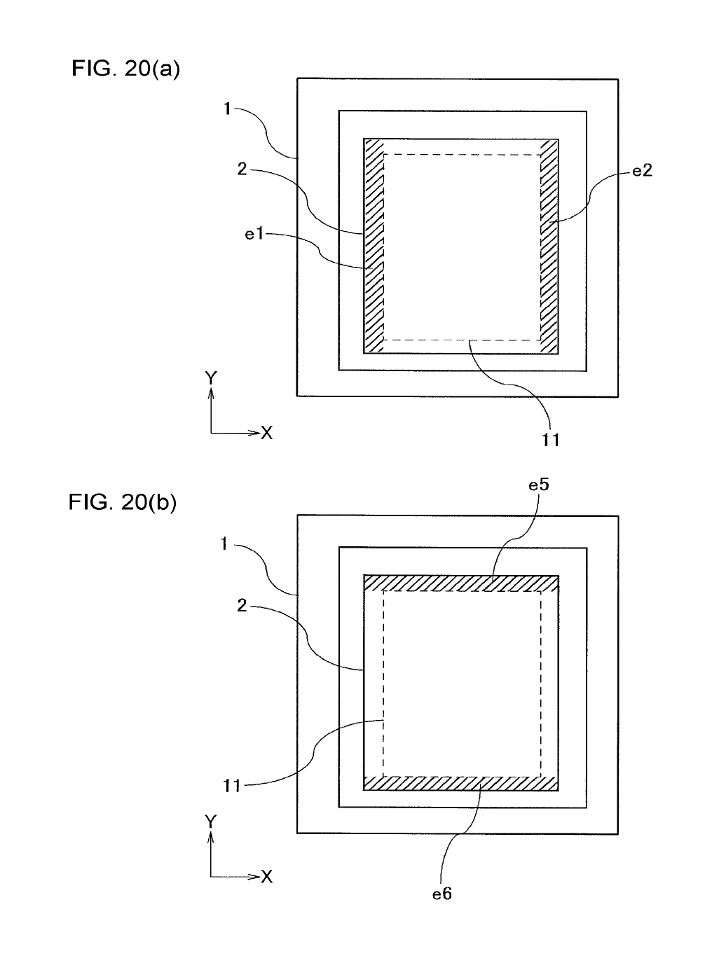

As shown in FIGS. 17 (a) and 17 (b), the coated film removing body 3 repeatedly scans the substrate in a direction parallel to the Y-axis direction in a state where the longitudinal direction of the removing unit 35 is in parallel to the X-axis direction, and further, the coated film removing body 3 repeatedly scans the substrate in a direction parallel to the X-axis direction in a state where the longitudinal direction of the removing unit 35 is in parallel to the Y-axis direction. Thus, unnecessary coated film 2 in the film-formation-unneeded regions e1, e2, e5 and e6 is sequentially removed, the film-formation-unneeded regions e1, e2, e5 and e6 being located at four outer peripheral edges of the necessary film-formation region, indicated by an oblique region shown in FIGS. 20 (a) and (b). Accordingly, hence, remaining coated film 2 was removed in the outer periphery of the necessary film-formation range of 80 mm×80 mm, and a desired condition was confirmed where no removing liquid 8 spread into the necessary film-formation region 11.

### Example 5-2

In the example 5-2, since the necessary film-formation region 11 is a rectangular shape, the coated film 2 was removed with a coated film removing body 3 having a surface shape (L-shape similar to that of FIGS. 13 and 14) of the removing unit 35 capable of simultaneously removing two edges. In this case, a bottom surface area of the removing unit 35 in the coated film removing body 3 is set such that each of the two edges each extending from the L-shaped corner portion is 100 mm and the width of each edge is 10 mm. The distances h1 to h3 between each of the removing liquid supplying openings 51a and 52a and the removing liquid collection opening 61a, and the substrate 1 are set based on the condition (5) shown in table 11 of the example 5-1.

Similar to the example 5-1, for the substrate 1, non-alkali glass OA-10 (manufactured by Nippon Electric Glass Co., Ltd), 120 mm×120 mm×0.7 mm was used, and the necessary film-formation range was set as 80 mm×80 mm. Then, two edges were simultaneously removed to fit the shape of the removing unit 35, in the unnecessary coated film 2 of the four outer peripheral sides.

The coated film removing body 3 repeatedly scanned the substrate, changing a scanning direction by 180 degrees, and the unnecessary coated film 2 was successively removed in the film-formation-unneeded regions e1, e2, e5 and e6 formed of four outer sides of the necessary film-formation range. Hence, remaining coated film was removed in the outer periphery of the necessary film-formation range of 80 mm×80 mm, and a desired condition was confirmed where no removing liquid 8 was spreading into the necessary film-formation range.

According to the present example, two edges of the unnecessary coated film 2 were simultaneously removed in the film-formation-unneeded regions e1, e2, e5 and e6 formed of four outer sides of the necessary film-formation range, whereby only two process steps are required, for one necessary film-formation range, to complete removal of the film-formation-unneeded region. As a result, it was confirmed that the processing time was shortened.

### Example 5-3

In the example 5-1, the temperature condition of the removing liquid 8 was 24° C. at the condition shown in (5) of the table 11. However, according to the Example 5-3, the temperature condition of the removing liquid 8 was changed to 30° C. from 24° C., and similarly, the coated film 2 was removed. For conditions other than the temperature condition of the removing liquid 8, the same condition as the example 5-1 was used.

As a result, comparing with the case where the coated film was removed in about 30 seconds when the temperature of the removing liquid 8 was 24° C., the period required for removing the coated film 2 was shortened to approximately 20 seconds, when the temperature of the removing liquid was 30° C. Hence, the removal performance was significantly improved. When the temperature of the removing liquid 8 was increased more, the removal performance was further improved.

However, when increasing the temperature higher than 40° C., a gain in the removal performance is limited so that effect is not significant. Moreover, on the other hand, an influence of steam will be a concern. Accordingly, when the temperature condition is determined, consideration is required for the apparatus and materials to be used.

Thus, the coated film 2 can reliably be removed in an outer peripheral portion of organic light emission pixel so that a polymer organic EL panel can be produced, in which a coating method forming simply and with uniformity is applied to a film-formation of the common layer which requires no separate-coating for each pixel of the hole transport layer and the hole injection layer or the like.

### Example 5-4

As a different example of a coated film removing apparatus 105 according to the fifth embodiment, in the following description sets forth the case where, in a film formation process of a photosensitive resin layer of a color filter used for liquid crystal display, an organic material forming the photosensitive resin layer is coated on the substrate 1 with a slit die, and unnecessary coated film is removed in the outer periphery of a pixel region as a necessary film-formation range.

As a material for a photosensitive resin to be coated, OFPR-800 manufactured by TOKYO OHKA KOGYO CO, LTD was used, and as the removing liquid 8, a sodium carbonate aqueous solution of 1.0 wt % at 30° C. was used.

As for the removing process, similar to the example 5-2, the coated film 2 was removed with a coated film removing body 3 having a surface shape (L-shape similar to that of FIGS. 13 and 14) of the removing unit 35 capable of simultaneously removing two edges. In this case, a bottom surface area of the removing unit 35 in the coated film removing body 3 is set such that each of the two edges each extending from the L-shaped corner portion is 100 mm and the width of each edge is 10 mm. The distances h1 to h3 between each of the removing liquid supplying openings 51a and 52a and the removing liquid collection opening 61a, and the substrate 1 are set based on the condition (5) shown in table 11 of the example 5-1.

Similar to the example 5-2, for the substrate 1, non-alkali glass OA-10 (manufactured by Nippon Electric Glass Co., Ltd), 120 mm×120 mm×0.7 mm was used, and the necessary film-formation range was set as 80 mm×80 mm. Then, two edges were simultaneously removed to fit the shape of the removing unit 35, in the unnecessary coated film 2 of the four outer peripheral sides.

The coated film removing body 3 repeatedly scanned the substrate, changing a scanning direction by 180 degrees, and the unnecessary coated film 2 was successively removed in the film-formation-unneeded regions e1, e2, e5 and e6 formed of four outer sides of the necessary film-formation range. Hence, remaining coated film was removed in the outer periphery of the necessary film-formation range of 80 mm×80 mm, and a desired condition was confirmed where no removing liquid 8 was spreading into the necessary film-formation range.

According to the present example, two edges of the unnecessary coated film 2 was simultaneously removed in the film-formation-unneeded regions e1, e2, e5 and e6 formed of four outer sides of the necessary film-formation range, whereby only two process steps are required, for one necessary film-formation range, to complete removal of the film-formation-unneeded region. As a result, it was confirmed that the processing time was shortened.

As described, examples 5-1 to 5-4 have been described. However, the present invention is not limited to the above-described examples. As described, examples of the organic EL display and the color filter used for the liquid crystal display have been described. However, it is not limited to these examples, but the above examples may be applied to a film formation substrate for other purposes. Also, the coated film 2 is not limited to a material used for an organic EL such as the hole transport layer, or a photosensitive resin used for a color filter of the liquid crustal display, but may be applied to materials for other purposes. The removing liquid 8 can be appropriately selected depending on the material of the coated film 2, for example, organic solvent and etchant or the like can be selected.

(About Organic EL Element)

According to first to fifth embodiments, examples were described with a major example of manufacturing an organic EL display. Hereinafter, a configuration of the organic EL display, in particular, a configuration of the organic EL element included in the organic EL display panel will be simply described.

The organic EL element is configured of a conductive organic light-emitting medium layer including an organic light-emitting layer made of an organic light-emitting material. The conductive organic light-emitting medium layer is applied with voltage to recombine injected electron and hole so as to make the organic light-emitting material emit light, when being recombined. In both sides of the organic light-emitting medium layer, a first electrode and a second electrode are provided to apply voltage to the organic light-emitting layer, thereby extracting light towards outside.

This organic EL element is configured of a first electrode, an organic light-emitting layer and a second electrode (counter electrode) which are successively laminated onto the transparent substrate. Usually, the first electrode formed on the substrate is used as an anode, and the counter electrode formed on the organic light-emitting layer is used as a cathode.

Further, to increase a light emitting efficiency, usually, a hole transport layer and a hole injection layer located between the anode and the organic light-emitting layer, and an electron transport layer and an electron injection layer located between the organic light-emission layer and the cathode are selectively provided appropriately to constitute an organic EL element. A laminate composed of the above-described organic light-emitting layer, hole transport layer, hole injection layer, electron transport layer and electron injection layer is referred to as an organic light-emitting medium layer.

Typically, the substance (light-emitting medium material) which constitutes and serves the organic light-emitting medium layer is low molecular weight compound. Each of the layers is laminated by a vacuum deposition method or the like such as resistive heating method, with a thickness within a range about 1 nm to 100 nm. Therefore, to manufacture the organic EL element using low molecular weight compound, a vacuum deposition apparatus is required in which a plurality of deposition chambers are connected to each other. Accordingly, productivity may be lowered and a manufacturing cost may be increased.

As the organic light-emitting medium layer of the EL element, a coating type material can be used.

For the light-emitting medium layer, following materials can be used, including a material in which low molecular light-emitting pigment is dissolved into a solvent such as toluene, xylene; or a material in which a low molecular light-emitting pigment is dissolved into a polymer compound such as polystyrene, polymethyl methacrylate, polyvinyl carbazole; or a material such as polyphenylene vinylene derivative (PPV), or a polyalkyl fluorene derivative (PAF). According to the EL element using these coating type materials, a material is dissolved or dispersed into a solvent, thereby forming the coated film composing layers of the organic light-emitting medium layer with a wet method such as a coating method or a printing method. Accordingly, the EL element using a coating type material is capable of forming films (formation of respective layers) under atmospheric pressure compared to the EL element using the above-described vacuum deposition method, thereby obtaining advantage where the equipment cost is lowered.

The above-described wet method, e.g., coating method includes spin coating method, bar coating method, slit coating method, and dip coating method. These coating methods are used effectively, especially when the high precision patterning is not necessary, since these coating methods form films simply and uniformly. These wet methods are effective for forming a common layer such as hole transport layer and hole injection layer which requires no separate-coating for each pixel.

On the other hand, when high precision patterning or RGB three-color separate-coating is required, a thin film forming is the most effective, using printing method such as intaglio printing, letterpress printing, planography, screen printing, ink jet printing or the like.

Next, a sealing process will be described, which is a post process after forming a cathode on the laminated organic light-emitting medium layer.

When leaving a state where the cathode has been formed on the organic light-emitting medium layer, moisture (water vapor) and oxygen are likely to influence the state to cause degradation of emission characteristics or degradation of metal electrodes, thereby producing a non-emission failure referred to as a dark spot. Accordingly, a sealing glass substrate is generally used for sealing, in which moisture absorbent is disposed in a portion facing the display region in a chamber that minimizes moisture and oxygen therein.

In the case where the sealing glass substrate is formed on a substrate having an organic light-emitting medium layer formed thereon, a prescribed distance (sealing space) is required for adhering the substrate on which the organic light-emitting medium layer is formed and the sealing glass substrate. In this case, to obtain sufficient sealing properties, it is preferable that an organic material which composes the organic light-emitting medium layer is not coated in the sealing space. However, when forming the hole transport layer and the hole injection layer with coating method, the organic material is formed even in the sealing space, possibly causing loss of sealing properties.

As a countermeasure, a printing method is used to form the hole transport layer and the hole injection layer which require no patterning, thereby forming the layers only for necessary area thereof.

As a method for removing a coating formed in the film-formation-unneeded region, for example, there is a method in which a portion having unnecessary coating (e.g., substrate edge portion) is immersed in a storage unit storing solution to remove the coating, thereby removing the unnecessary coating (See PTL 1 and PTL 2).

According to conventional coating methods, there have been issues in view of simplicity and uniformity in film-forming, and selectivity of printing materials or the like. Therefore, it is desired to use a coating method having better performance in this view in this technical field of the present invention.

According to a conventional method of removing a film in which a coated region of the film is soaked into a storage portion of solvent, portions to be removed may be limited to, e.g., end portions of a substrate. Hence, a high-versatile method has been desired, e.g., a method capable of removing film in any portions.

An object of the present invention is to provide a coated film removing apparatus capable of readily and accurately removing a coated film which is coated on a film-formation-unneeded region, during a manufacturing process of an organic EL panel or the like.

The coated film removing apparatus according to one aspect of the present invention is characterized in that the apparatus is provided with a coated film removing body and a process gap adjustment device.

The coated film removing body includes removing liquid supplying means for discharging removing liquid from a discharge opening to a coated film removal portion located at a predetermined portion in a coated film on a substrate, and removing liquid collection means for to collecting, from a collection opening, the discharged removing liquid. The process gap adjustment device adjusts a distance from a surface of the substrate, to a flat bottom surface located between the discharge opening and the collection opening of the coated film removing body.

According to one aspect of the present invention, a part of the coated film formed on the substrate can be selectively removed easily and accurately. Therefore, a coated film removing apparatus can be provided, capable of removing coated film in an outer periphery of an organic light emission pixel or the like. As a result, sealing properties can be improved and a polymer organic EL panel having fewer defects in the light emission pixels can readily be obtained.

As described, with reference to specific embodiments, the present invention has been described. However, the present invention is not limited to these descriptions. Referring to the descriptions of the present invention, it is apparent for person having ordinary skill in the art to analogize another embodiment together with various modifications obtained from the disclosed embodiments. Accordingly, it should be understood that a scope of claims covers these modifications and the embodiments within scope and the subject matter of the present invention. In other words, the present invention may be combined with the above-described embodiments. Specifically, the coated film removing apparatus according to the present invention may combine the first embodiment with the second to fifth embodiments.

### REFERENCE SIGNS LIST

1: substrate
2: coated film
3: coated film removing body
3a, 3b: moving unit
4: height measurement device
5: removing liquid supplying means
5a: removing liquid supplying opening
5b: removing liquid supplying unit
5c: removing liquid detecting means
6: removing liquid collection means
6a: removing liquid collection opening
6b: removing liquid collection unit
6c: removing liquid detecting means
7: gas supplying unit
7a: gas supplying opening
7b: gas supplying unit
8: removing liquid
9: ultrasonic vibration application unit
10: stage
11: necessary film-formation region
12: water repellent outer unit
13: height adjustment device
14: ultrasonic vibration application means
15: control device
19: bottom surface
20: control unit
21: guide rail
30-35: removing unit
31a-35a: moving unit
31b-35b: moving unit
51, 52: removing liquid supplying means
51a, 52a: removing liquid supplying opening
51b, 52b: removing liquid supplying unit
61: removing liquid collection means
61a: removing liquid collection opening
61b: removing liquid collection unit
100-105: coated film removing apparatus
e1-e7: film-formation-unneeded region
w1: width
h1-h3: distance

Obviously, numerous modifications and variations of the present invention are possible in light of the above teachings. It is therefore to be understood that within the scope of the appended claims, the invention may be practiced otherwise than as specifically described herein

What is claimed is:

1. An apparatus for removing a film coated on a substrate, comprising:
a film removing body including
a liquid supply device which discharges removing liquid through a discharge opening to a removal portion of a film coated on a substrate, and
a collection device which collects a discharged removing liquid through a collection opening; and
an adjustment device that adjusts a distance between a surface of the substrate to a bottom surface of the film removing body at a position between the discharge opening and the collection opening.

2. The apparatus of claim 1, further comprising:
a measurement device that measures a distance between the surface of the substrate and the bottom surface of the body,
wherein the adjustment device adjusts the distance based on a value measured by the measurement device.

3. The apparatus of claim 1, wherein the film removing body further includes a water repellent portion formed by applying a water repellent treatment to an outer peripheral portion of the discharge opening and the collection opening.

4. The apparatus of claim 3, wherein the water repellent portion has a water contact angle of 90 degrees or more.

5. The apparatus of claim 3, wherein the film removing body further includes a gas supplying unit which discharges gas to the substrate through a gas supplying opening formed outside of the water repellent portion such that the gas discharged through the gas supplying opening prevents the removing liquid from flowing towards outside the removal portion of the film.

6. The apparatus of claim 3, wherein the film removing body further includes a gas supplying unit which discharges gas comprising nitrogen gas to the substrate through a gas supplying opening formed outside of the water repellent portion such that the gas discharged through the gas supplying opening prevents the removing liquid from flowing towards outside the removal portion of the film.

7. An apparatus for removing a film coated on a substrate, comprising:
a film removing body including
a liquid supply device which discharges removing liquid to a removal portion of a film coated on a substrate, and
a collection device which collects a discharged removing liquid through a collection opening,
wherein the liquid supply device has at least one discharge opening for discharging the removing liquid, and the collection device has at least one collection opening for collecting the removing liquid.

8. The apparatus of claim 7, wherein the at least one discharge opening is two discharge openings, the collection opening is one collection opening, and the film removing body is in an L shape in plan view.

9. The apparatus of claim 7, wherein the film removing body has a bottom surface which is inclined in a height direction with respect to the surface of the substrate such that a first distance between the surface of the substrate and the bottom surface at a position of the discharge opening is different from a second distance between the surface of the substrate and the bottom surface at a position of the collection opening.

10. An apparatus for removing a film coated on a substrate, comprising:
a film removing body including
a liquid supply device which discharges removing liquid through a discharge opening to a removal portion of a film coated on a substrate, and
a collection device which collects a discharged removing liquid through a collection opening,
wherein the film removing body has a bottom surface between the discharge opening and the collection opening, and
the film removing body has a bottom surface positioned at a distance from a surface of the substrate, and the distance measured at a first position of the bottom surface where the discharge opening is located is different from the distance measured at a second position of the bottom surface where the collection opening is located.

11. The apparatus of claim 10, wherein the distance at the first position is greater than the distance at the second position.

12. The apparatus of claim 10, wherein the bottom surface of the film removing body is inclined by 0.05 degrees or more in a height direction with respect to the surface of the substrate.

13. The apparatus of claim 10, wherein the distance at the first position is 3 mm or less.

14. The apparatus of claim 10, wherein the distance at the first position is 2 mm or less.

15. The apparatus of claim 10, further comprising:
an adjustment device that adjusts the distance between the bottom surface and the surface of the substrate.

16. The apparatus of claim 15, further comprising:
a measurement device that measures the distance between the bottom surface and the surface of the substrate,
wherein the adjustment device adjusts the distance based on a value measured by the measurement device.

17. The apparatus of claim 10, wherein the distance at the first position is greater than the distance at the second position by 0.1 mm or more.

18. The apparatus of claim 15, further comprising:
a control unit that causes the adjustment device to adjust the bottom surface to be inclined by 0.05 degrees or more in a height direction with respect to the surface of the substrate, when the removing liquid is present in a portion between the bottom surface of the film removing body and the surface of the substrate.

19. The apparatus of claim 15, further comprising:
a control unit that causes the adjustment device to adjust the distance to be 3.0 mm or less, when the removing liquid is present in a portion between the bottom surface of the film removing body and the surface of the substrate.

20. The apparatus of claim 15, further comprising:
a control unit that causes the adjustment device to change an inclination of the bottom surface with respect to the surface of the substrate at least one time, when the removing liquid is present in a portion between the bottom surface of the film removing body and the surface of the substrate.

21. The apparatus of claim 18, further comprising:
a measurement device that measures the distance between the surface of the substrate and the bottom surface,
wherein the control unit causes the adjustment device to adjust the distance between the surface of the substrate and the bottom surface based on a value measured by the measurement device.

22. The apparatus of claim 18, further comprising:
a control unit including
a first processing unit that sets the distance at the first position to be longer than the distance at the second position, before the removing liquid is supplied through the discharge opening,
a second processing unit that alternately changes inclination of the bottom surface with respect to the surface of the substrate at least one time, when the second processing unit determines that removing liquid is discharged through the discharge opening, and
a third processing unit that sets the distance at the first position to be shorter than the distance at the second position, when the third processing unit determines that removing liquid is collected through the collection opening.

23. The apparatus of claim 10, further comprising:
a height adjusting device that adjusts the distance to be different between the first position and the second position,
wherein the film removing body further includes a detecting device that detects the removing liquid in portions where the discharge opening and the collection opening are located.

24. The apparatus of claim 23, further comprising:
a control unit that controls a supply quantity and a collection quantity of the removing liquid based on a detection result of the detecting device.

25. The apparatus of claim 23, wherein the height adjusting device comprises an adjustment device that adjusts the distance at the first position and the distance at the second position individually.

26. The apparatus of claim 25, further comprising:
a measurement device that measures the distance between the surface of the substrate and the bottom surface,
wherein the adjustment device adjusts the distance based on a value measured by the measurement device.

27. The apparatus of claim 10, wherein the collection device collects the removing liquid when a holding time elapses after the removing liquid is discharged through the discharge opening.

28. The apparatus of claim 10, further comprising:
an ultrasonic vibration application unit that applies ultrasonic vibration to the removing liquid discharged to the removal portion of the film.

29. The apparatus of claim 10, wherein a temperature of the removing liquid discharged to the removal portion of the film is set within a range from 30° C. to 40° C.

30. The apparatus of claim 10, wherein the discharge opening and the collection opening are movable parallel to the surface of the substrate such that measuring and adjusting of the distance, and discharging and collecting of removing liquid, are performed in the removal portion of the film.
